(19) United States
(12) Patent Application Publication
(10) Pub. No.: US 2012/0183902 A1
(43) Pub. Date: Jul. 19, 2012

(54) RADIATION-SENSITIVE RESIN COMPOSITION

(75) Inventors: Hiroki Nakagawa, Tokyo (JP); Takehiko Naruoka, Tokyo (JP); Shinichi Nakamura, Tokyo (JP); Kazuki Kasahara, Tokyo (JP)

(73) Assignee: JSR Corporation, Tokyo (JP)

(21) Appl. No.: 13/338,260

(22) Filed: Dec. 28, 2011

Related U.S. Application Data
(63) Continuation of application No. PCT/JP2010/061328, filed on Jul. 2, 2010.

(30) Foreign Application Priority Data
Jul. 2, 2009 (JP) 2009-158122

(51) Int. Cl. G03F 7/027

(52) U.S. Cl. 430/284.1; 430/281.1

(57) ABSTRACT

A radiation-sensitive resin composition includes an acid-labile group-containing resin, a radiation-sensitive acid generating agent, and an acid diffusion controller including a first compound shown by a following general formula (1-1) and a second compound shown by a following general formula (1-2) or (1-3). In the formula (1-1), each of R¹ and R² individually represents a hydrogen atom or the like, and R^{p} represents an acid-labile group. In the formula (1-2), R³ represents a hydrogen atom or the like, and each of R⁴ to R⁶ individually represents a hydrogen atom or the like. In the formula (1-3), R³ represents a hydrogen atom or the like, R^{q} represents a single bond or the like, and each of R⁵ and R⁶ individually represents a hydrogen atom or the like.

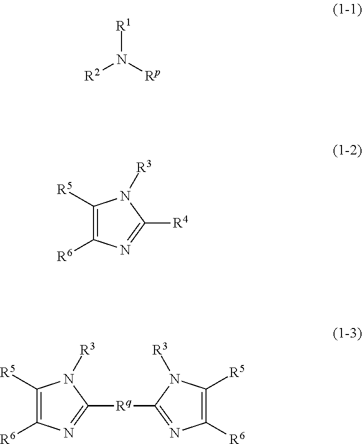

### CROSS-REFERENCE TO RELATED APPLICATIONS

The present application is a continuation application of International Application No. PCT/JP2010/061328, filed Jul. 2, 2010, which claims priority to Japanese Patent Application No. 2009-158122, filed Jul. 2, 2009. The contents of these applications are incorporated herein by reference in their entirety.

### BACKGROUND OF THE INVENTION

1. Field of the Invention

The invention relates to a radiation-sensitive resin composition.

2. Discussion of the Background

In the field of microfabrication (e.g., production of integrated circuit element), a reduction in line width implemented by lithography has progressed in order to achieve a higher degree of integration. Therefore, use of radiation having a shorter wavelength has been extensively studied. Examples of such short-wavelength radiation include a bright line spectrum of a mercury lamp (wavelength: 254 nm), far-ultraviolet rays (e.g., KrF excimer laser light (wavelength: 248 nm) and ArF excimer laser light (wavelength: 193 nm)), X-rays (e.g., synchrotron radiation), and charged particle rays (e.g., electron beams). Among them, lithography that utilizes excimer laser light has been particularly attracted attention due to high output, high efficiency, and the like.

It has been desired to fond a fine resist pattern having a line width of about 45 nm using short-wavelength radiation, such as excimer laser light. Such a fine pattern may be formed by shortening the wavelength of the light source of the exposure device, or increasing the numerical aperture (NA) of the lens, for example. However, a new expensive exposure device is required to shorten the wavelength of the light source. In the case of increasing the numerical aperture of the lens, since the resolution and the depth of focus have a trade-off relationship, there is a problem that a decrease in depth of focus may occur even if the resolution can be increased.

So, in recent years, liquid immersion lithography has been proposed as lithographic technology that can solve the above problem. Liquid immersion lithography provides an immersion exposure liquid (e.g., purified water or fluorine-containing inert fluid) between the lens and the resist film (over the resist film) during exposure. According to this liquid immersion lithography, the exposure optical space which was conventionally filled with air or an inert gas (e.g., nitrogen) is filled with an immersion exposure liquid that has a refractive index (n) higher than that of air and the like. Therefore, the same effect as that achieved when shortening the wavelength of exposure light can be achieved even if in the case of using the conventional wavelength of exposure light. That is, high resolution can be obtained without decreasing depth of focus.

According to liquid immersion lithography, a resist pattern that exhibits high resolution and an excellent depth of focus can be inexpensively formed even if the lens provided in an existing device are used. For example, WO04/068242 discloses a resist composition used for liquid immersion lithography. JP-A-2002-82438 discloses a radiation-sensitive resin composition including a low molecular weight compound having at least an amino group substituted by t-butoxy carbonyl group, and JP-A-2007-240631 discloses a positive type resist composition including a basic compound having a specific benzimidazole derivative.

### SUMMARY OF THE INVENTION

According to one aspect of the present invention, a radiation-sensitive resin composition includes an acid-labile group-containing resin, a radiation-sensitive acid generating agent, and an acid diffusion controller including a first compound shown by a general formula (1-1) and a second compound shown by a general formula (1-2) or a general formula (1-3).

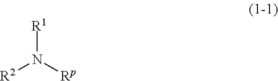

In the formula (1-1), each of R¹ and R² individually represents a hydrogen atom, a linear or branched alkyl group, a cycloalkyl group, an aryl group or an aralkyl group, or each of R¹ and R² individually represents a hydrogen atom, a linear or branched alkyl group, a cycloalkyl group, an aryl group or an aralkyl group and R¹ and R² bond to each other to form a substituted or unsubstituted heterocyclic hydrocarbon group having 1 to 20 atoms together with a nitrogen atom bonded to R¹ and R². R^{p} represents an acid-labile group.

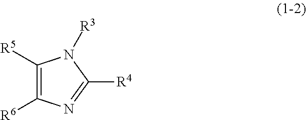

In the formula (1-2), R³ represents a hydrogen atom, a substituted or unsubstituted alkyl group having 1 to 20 carbon atoms, a substituted or unsubstituted alicyclic hydrocarbon group having 3 to 20 carbon atoms, an alkenyl group having 2 to 20 carbon atoms, a substituted or unsubstituted aryl group, or a substituted or unsubstituted heteroaryl group. Each of R⁴ to R⁶ individually represents a hydrogen atom or a substituted or unsubstituted aryl group, or each of R⁴ to R⁶ individually represents a hydrogen atom or a substituted or unsubstituted aryl group and two of R⁴ to R⁶ bond to each other to form a ring that optionally includes a heteroatom.

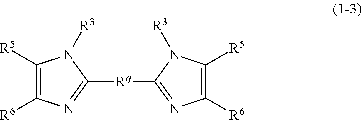

In the formula (1-3), R³ represents a hydrogen atom, a substituted or unsubstituted alkyl group having 1 to 20 carbon atoms, a substituted or unsubstituted alicyclic hydrocarbon group having 3 to 20 carbon atoms, an alkenyl group having 2 to 20 carbon atoms, a substituted or unsubstituted aryl group, or a substituted or unsubstituted heteroaryl group. R^{q} represents a single bond, a substituted or unsubstituted methylene group, a substituted or unsubstituted alkylene group having 2 to 20 carbon atoms, a substituted or unsubstituted alicyclic hydrocarbon group having 3 to 20 carbon atoms, an alkenylene group having 2 to 20 carbon atoms, a substituted or unsubstituted arylene group, or a substituted or unsubstituted heteroarylene group. Each of R⁵ and R⁶ individually represents a hydrogen atom or a substituted or unsubstituted aryl group, or each of R⁵ and R⁶ individually represents a hydrogen atom or a substituted or unsubstituted aryl group and R⁵ and R⁶ bond to each other to form a ring that optionally includes a heteroatom.

### DESCRIPTION OF THE EMBODIMENTS

That is, an embodiment of the invention provides the following radiation-sensitive resin composition.

[1] A radiation-sensitive resin composition including an acid-labile group-containing resin (A) (hereinafter may be referred to as “resin (A)”), a radiation-sensitive acid generating agent (B) (hereinafter may be referred to as “acid generating agent (B)”), and an acid diffusion controller (C) including a compound (C1) shown by a general formula (1-1) (hereinafter may be referred to as “compound (C1)”) and a compound (C2) shown by a general formula (1-2) or (1-3) (hereinafter may be referred to as “compound (C2)”),

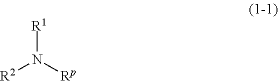

wherein R¹ and R² individually represent a hydrogen atom, a linear or branched alkyl group, a cycloalkyl group, an aryl group, or an aralkyl group, provided that R¹ and R² may bond to each other to form a substituted or unsubstituted heterocyclic hydrocarbon group having 1 to 20 atoms together with a nitrogen atom bonded to R¹ and R², and R^{p} represents an acid-labile group,

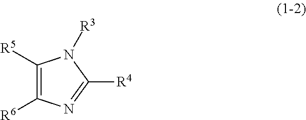

wherein R³ represents a hydrogen atom, a substituted or unsubstituted alkyl group having 1 to 20 carbon atoms, a substituted or unsubstituted alicyclic hydrocarbon group having 3 to 20 carbon atoms, an alkenyl group having 2 to 20 carbon atoms, a substituted or unsubstituted aryl group, or a substituted or unsubstituted heteroaryl group, and R⁴ to R⁶ individually represent a hydrogen atom or a substituted or unsubstituted aryl group, provided that two of R⁴ to R⁶ may bond to each other to form a ring that may include a heteroatom,

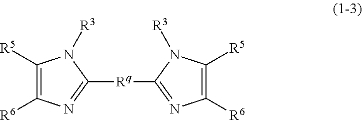

wherein R³ represents a hydrogen atom, a substituted or unsubstituted alkyl group having 1 to 20 carbon atoms, a substituted or unsubstituted alicyclic hydrocarbon group having 3 to 20 carbon atoms, an alkenyl group having 2 to 20 carbon atoms, a substituted or unsubstituted aryl group, or a substituted or unsubstituted heteroaryl group, R^{q} represents a single bond, a substituted or unsubstituted methylene group, a substituted or unsubstituted alkylene group having 2 to 20 carbon atoms, a substituted or unsubstituted alicyclic hydrocarbon group having 3 to 20 carbon atoms, an alkenylene group having 2 to 20 carbon atoms, a substituted or unsubstituted arylene group, or a substituted or unsubstituted heteroarylene group, and R⁵ and R⁶ individually represent a hydrogen atom or a substituted or unsubstituted aryl group, provided that R⁵ and R⁶ may bond to each other to form a ring that may include a heteroatom.
[2] The radiation-sensitive resin composition according to [1], wherein the amount of the compound (C2) is 1 to 99 parts by mass based on 100 parts by mass of the acid diffusion controller (C).
[3] The radiation-sensitive composition according to [1] or [2], wherein the compound (C1) is a compound shown by a general formula (1-1a),

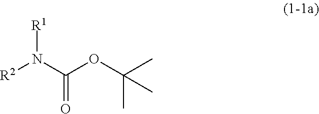

wherein R¹ and R² individually represent a hydrogen atom, a linear or branched alkyl group, a cycloalkyl group, an aryl group, or an aralkyl group, provided that R¹ and R² may bond to each other to form a substituted or unsubstituted heterocyclic hydrocarbon group having 1 to 20 atoms together with a nitrogen atom bonded to R¹ and R².
[4] The radiation-sensitive resin composition according to any one of [1] to [3], wherein the acid-labile group-containing resin (A) includes a repeating unit shown by a general formula (2-1) (hereinafter may be referred to as “repeating unit (2-1)”) and a repeating unit shown by a general formula (2-2) (hereinafter may be referred to as “repeating unit (2-2)”),

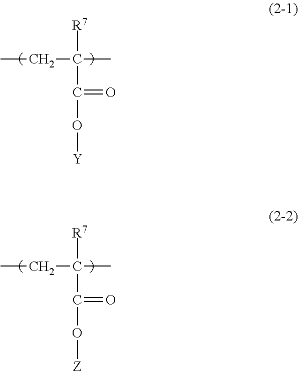

wherein R⁷ represents a hydrogen atom, a methyl group, or a trifluoromethyl group, Y represents an acid-labile group, and Z represents a group that includes a lactone skeleton or a cyclic carbonate structure.
[5] The radiation-sensitive resin composition according to [4], wherein Y in the general formula (2-1) represents a group shown by a general formula (1),

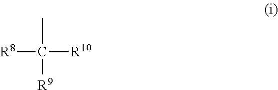

wherein R⁸ represents an alkyl group having 1 to 4 carbon atoms or a monovalent alicyclic hydrocarbon group having 4 to 20 carbon atoms, and R⁹ and R¹⁰ individually represent an alkyl group having 1 to 4 carbon atoms or a monovalent alicyclic hydrocarbon group having 4 to 20 carbon atoms, provided that R⁹ and R¹⁰ may bond to each other to form an alicyclic hydrocarbon group having 4 to 20 carbon atoms together with a carbon atom bonded to R⁹ and R¹⁰.
[6] The radiation-sensitive resin composition according to any one of [1] to [5], further including a fluorine-containing polymer (D) (hereinafter may be referred to as “polymer (D)”).
[7] The radiation-sensitive resin composition according to [6], wherein the amount of the fluorine-containing polymer (D) is 0.1 to 20 parts by mass based on 100 parts by mass of the acid-labile group-containing resin (A).

The above radiation-sensitive resin composition of the embodiment of the present invention can form a resist pattern excellent in the depth of focus, LWR, MEEF, and cross-sectional shape.

Embodiments of the present invention are described below. Note that the present invention is not limited to the following embodiments. It should be understood that various modifications, improvements, and the like may be made of the following embodiments without departing from the scope of the present invention based on common knowledge of a person skilled in the art.

### 1. Resin (A)

The resin (A) is not particularly limited as long as the resin is insoluble or scarcely soluble in an alkali, but becomes alkali-soluble through the addition of an acid. It is preferable that the resin (A) include the repeating unit (2-1) and the repeating unit (2-2). Incidentally, the expression “insoluble or scarcely soluble in an alkali” in this specification means such a property that 50% or more of the initial thickness remain when a film of 100 nm in the thickness having been formed by using only the resin (A) is subjected instead of a resist film formed by the radiation-sensitive resin composition including resin (A) to develop under alkaline development conditions, which employed for forming a resist pattern using a resin film formed of the radiation-sensitive resin composition.

(1) Repeating unit (2-1)

Y in the general formula (2-1) preferably represents the group shown by the general formula (i).

Examples of the alkyl group having 1 to 4 carbon atoms represented by R⁸ to R¹⁰ in the general formula (i) include a methyl group, an ethyl group, an n-propyl group, an i-propyl group, an n-butyl group, a 2-methylpropyl group, a 1-methylpropyl group, a t-butyl group, and the like. Examples of the monovalent alicyclic hydrocarbon group having 4 to 20 carbon atoms, and the alicyclic hydrocarbon group having 4 to 20 carbon atoms formed by R⁹ and R¹⁰ together with the carbon atom bonded to R⁹ and R¹⁰ include groups including a bridged skeleton such as an adamantane skeleton, a norbornane skeleton, a tricyclodecane skeleton, or a tetracyclododecane skeleton or a cycloalkane skeleton such as cyclobutane, cyclopentane, cyclohexane, cycloheptane, or cyclooctane; and groups having alicyclic skeleton obtained by substituting these groups with at least one linear or branched alkyl group having 1 to 10 carbon atoms (e.g., methyl group, ethyl group, n-propyl group, i-propyl group, n-butyl group, 2-methylpropyl group, 1-methylpropyl group, or t-butyl group) or cycloalkyl group.

Specific examples of a monomer that produces the repeating unit (2-1) include 2-methyladamantan-2-yl(meth)acrylate, 2-methyl-3-hydroxyadamantan-2-yl(meth)acrylate, 2-ethyladamantan-2-yl(meth)acrylate, 2-ethyl-3-hydroxyadamantan-2-yl(meth)acrylate, 2-n-propyladamantan-2-yl(meth)acrylate, 2-isopropyladamantan-2-yl(meth)acrylate, 2-methylbicyclo[2.2.1]hept-2-yl(meth)acrylate, 2-ethylbicyclo[2.2.1]hept-2-yl (meth)acrylate, 8-methyltricyclo[5.2.1.0^{2,6}]decan-8-yl(meth)acrylate, 8-ethyltricyclo[5.2.1.0^{2,6}]decan-8-yl(meth)acrylate, 4-methyltetracyclo[6.2.1.1^{3,6}.0^{2,7}]dodecan-4-yl(meth)acrylate, 4-ethyltetracyclo[6.2.1.1^{3,6}.0^{2,7}]dodecan-4-yl(meth)acrylate, 1-(bicyclo[2.2.1]hept-2-yl)-1-methylethyl(meth)acrylate, 1-(tricyclo[5.2.1.0^{2,6}]decan-8-yl)-1-methylethyl(meth)acrylate, 1-(tetracyclo[6.2.1.1^{3,6}.0^{2,7}]dodecan-4-yl)-1-methylethyl(meth)acrylate, 1-(adamantan-2-yl)-1-methylethyl(meth)acrylate, 1-(3-hydroxyadamantan-2-yl)-1-methylethyl(meth)acrylate, 1,1-dicyclohexylethyl (meth)acrylate, 1,1-di(bicyclo[2.2.1]hept-2-yl)ethyl(meth)acrylate, 1,1-di(tricyclo[5.2.1.0^{2,6}]decan-8-yl)ethyl(meth)acrylate, 1,1-di(tetracyclo[6.2.1.1^{3,6}. 0^{2,7}]dodecan-4-yl)ethyl(meth)acrylate, 1,1-di(adamantan-1-yl)ethyl(meth)acrylate, 1-methyl-1-cyclopentyl(meth)acrylate, 1-ethyl-1-cyclopentyl(meth)acrylate, 1-methyl-1-cyclohexyl(meth)acrylate, 1-ethyl-1-cyclohexyl(meth)acrylate, and the like.

Among these monomers, 2-methyladamantan-2-yl(meth)acrylate, 2-ethyladamantan-2-yl(meth)acrylate, 2-methylbicyclo[2.2.1]hept-2-yl(meth)acrylate, 2-ethylbicyclo [2.2.1]hept-2-yl(meth)acrylate, 1-methyl-1-cyclopentyl(meth)acrylate, 1-ethyl-1-cyclopentyl(meth)acrylate, 1-methyl-1-cyclohexyl(meth)acrylate, and 1-ethyl-1-cyclohexyl(meth)acrylate are preferable.

The resin (A) may include only one type of the repeating unit (2-1), or may include two or more types of the repeating unit (2-1).

The content ratio of the repeating unit (2-1) in the resin (A) is preferably 15 to 85 mol %, more preferably 25 to 75 mol %, and particularly preferably 35 to 60 mol %. If the content ratio is less than 15 mol %, the pattern shape may deteriorate by impairing the contrast after dissolution. On the other hand, if the content ratio exceeds 85 mol %, the resulting pattern may peel off due to insufficient adhesion to a substrate.

### (2) Repeating Unit (2-2)

Examples of a repeating unit which includes group having a lactone skeleton in the repeating unit (2-2) include repeating units shown by the following general formulas (2-2-1a) to (2-2-1f).

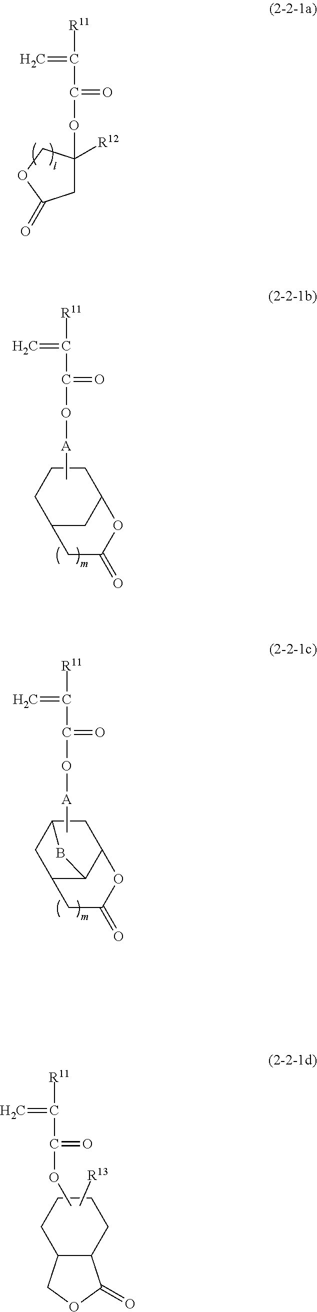

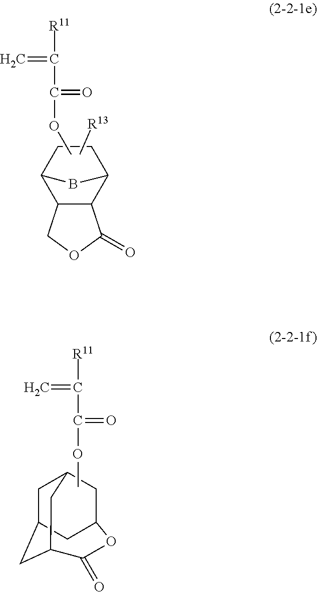

wherein R¹¹ represents a hydrogen atom or a methyl group, R¹² represents a hydrogen atom or a substituted or unsubstituted alkyl group having 1 to 4 carbon atoms, 1 is an integer from 1 to 3, R¹³ represents a hydrogen atom or a methoxy group, A represents a single bond, an ether group, an ester group, a carbonyl group, a divalent chain-like hydrocarbon group having 1 to 30 carbon atoms, a divalent alicyclic hydrocarbon group having 3 to 30 carbon atoms, a divalent aromatic hydrocarbon group having 6 to 30 carbon atoms, or a divalent group formed by combining arbitrary groups among these groups, in is 0 or 1, and B represents an oxygen atom or a methylene group.

Specific examples of a preferable monomer that produces the repeating unit which includes group having a lactone skeleton include 5-oxo-4-oxa-tricyclo[4.2.1.0^{3,7}]non-2-yl (meth)acrylate, 9-methoxycarbonyl-5-oxo-4-oxa-tricyclo[4.2.1.0^{3,7}]non-2-yl(meth)acrylate, 5-oxo-4-oxa-tricyclo[5.2.1.0^{3,8}]dec-2-yl(meth)acrylate, 10-methoxycarbonyl-5-oxo-4-oxa-tricyclo[5.2.1.0^{3,8}]dec-2-yl(meth)acrylate, 6-oxo-7-oxa-bicyclo[3.2.1]oct-2-yl(meth)acrylate, 4-methoxycarbonyl-6-oxo-7-oxa-bicyclo[3.2.1]oct-2-yl(meth)acrylate, 7-oxo-8-oxa-bicyclo [3.3.1]non-2-yl(meth)acrylate, 4-methoxycarbonyl-7-oxo-8-oxa-bicyclo[3.3.1]non-2-yl(meth)acrylate, 2-oxotetrahydropyran-4-yl(meth)acrylate, 4-methyl-2-oxotetrahydropyran-4-yl (meth)acrylate, 4-ethyl-2-oxotetrahydropyran-4-yl(meth)acrylate, 4-propyl-2-oxotetrahydropyran-4-yl(meth)acrylate, 5-oxotetrahydrofuran-3-yl(meth)acrylate, 2,2-dimethyl-5-oxotetrahydrofuran-3-yl(meth)acrylate, 4,4-dimethyl-5-oxotetrahydrofuran-3-yl(meth)acrylate, 2-oxotetrahydrofuran-3-yl (meth)acrylate, 4,4-dimethyl-2-oxotetrahydrofuran-3-yl(meth)acrylate, 5,5-dimethyl-2-oxotetrahydrofuran-3-yl(meth)acrylate, 5-oxotetrahydrofuran-2-ylmethyl (meth)acrylate, 3,3-dimethyl-5-oxotetrahydrofuran-2-ylmethyl(meth)acrylate, 4,4-dimethyl-5-oxotetrahydrofuran-2-ylmethyl(meth)acrylate, and the like.

Examples of a repeating unit which includes group having a cyclic carbonate structure in the repeating unit (2-2) include a repeating unit shown by the following general formula (2-2-2).

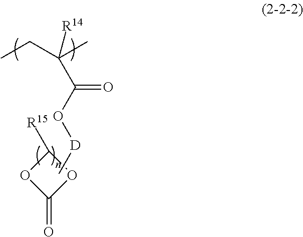

wherein R¹⁴ represents a hydrogen atom, a methyl group, or a trifluoromethyl group, R¹⁵ individually represent a hydrogen atom or a chain-like hydrocarbon group having 1 to 5 carbon atoms, D represents a single bond, a divalent or trivalent chain-like hydrocarbon group having 1 to 30 carbon atoms, a divalent or trivalent alicyclic hydrocarbon group having 3 to 30 carbon atoms, or a divalent or trivalent aromatic hydrocarbon group having 6 to 30 carbon atoms, provided that a carbon atom included in D is bonded to a carbon atom that forms the cyclic carbonate to form a cyclic structure when D represents a trivalent group, and n is an integer from 2 to 4.

A monomer that produces the repeating unit shown by the general formula (2-2-2) may be synthesized by the known method, such as disclosed in Tetrahedron Letters, Vol. 27, No. 32, p. 3741 (1986), Organic Letters, Vol. 4, No. 15, p. 2561 (2002), or the like.

Examples of a particularly preferable repeating unit shown by the general formula (2-2-2) include repeating units shown by the following general formulas (2-2-2a) to (2-2-2v). Note that R¹⁴ in the general formulas (2-2-2a) to (2-2-2v) represents a hydrogen atom, a methyl group, or a trifluoromethyl group.

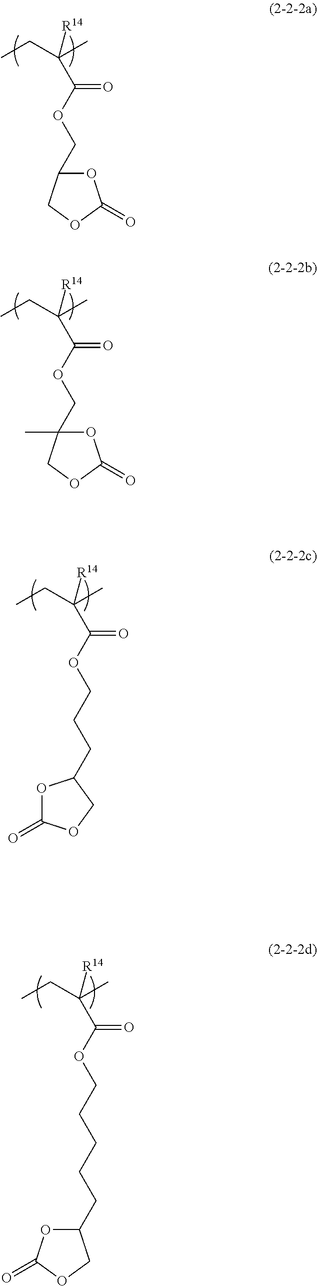

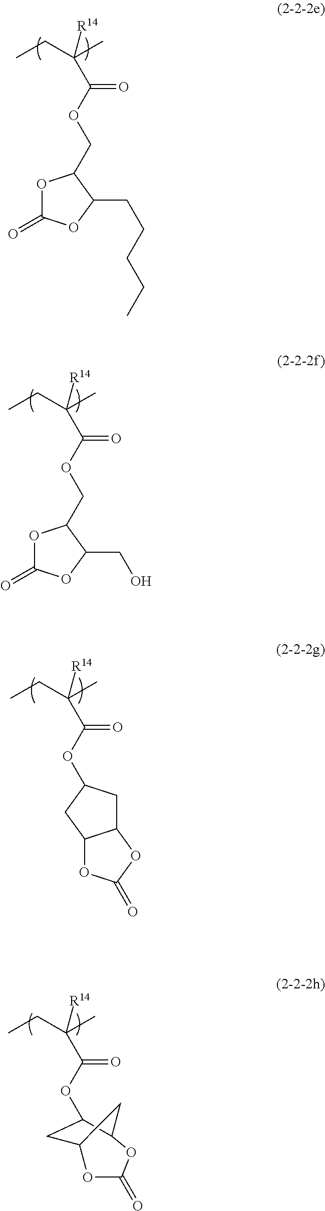

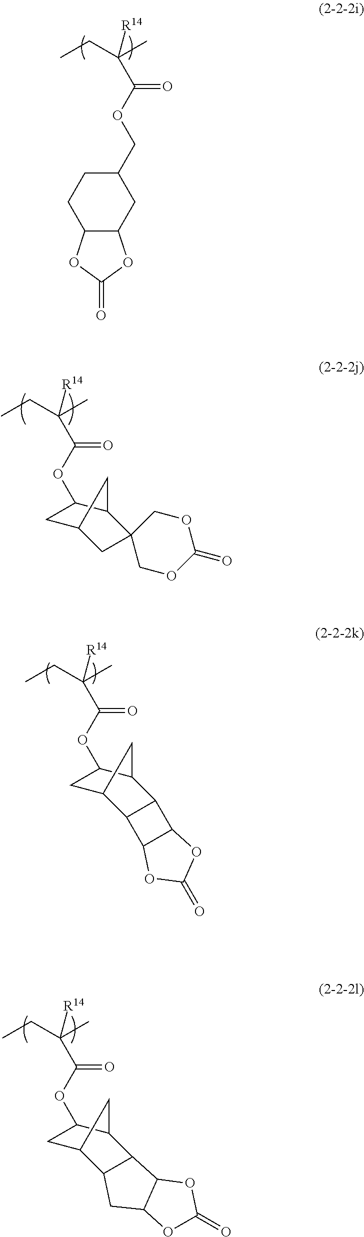

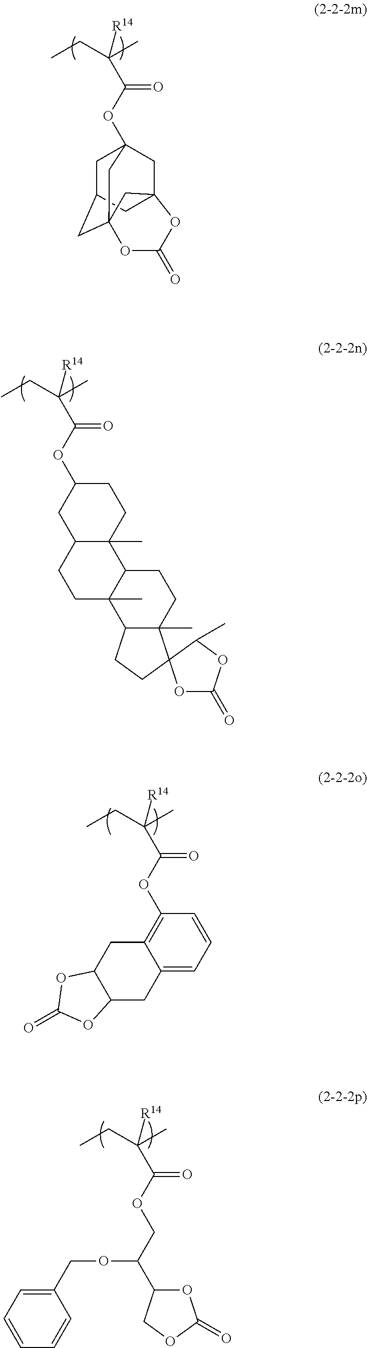

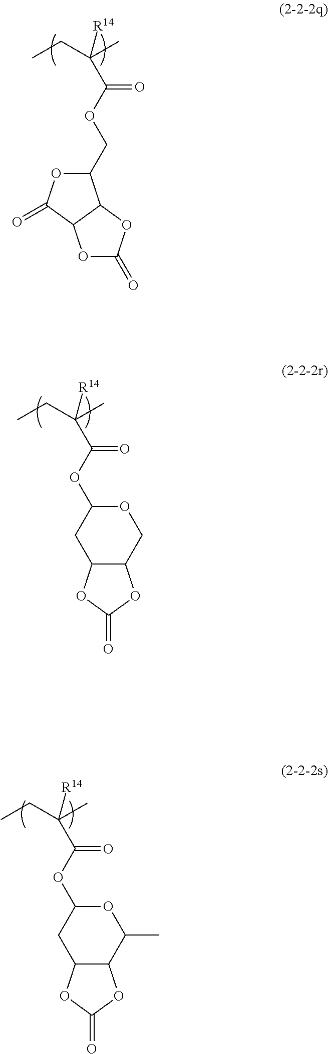

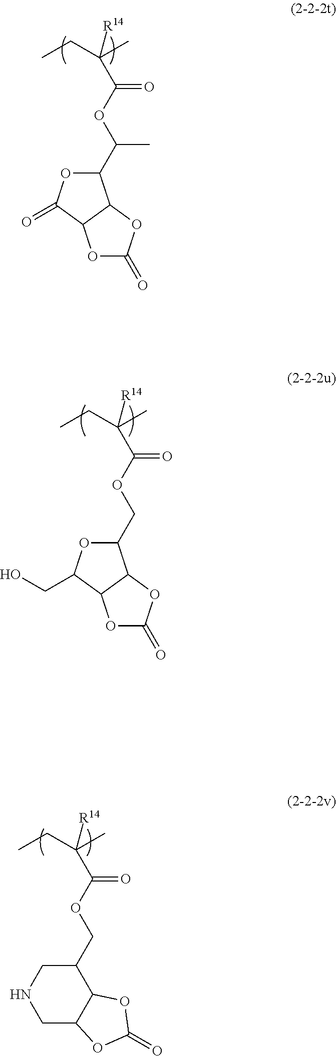

The resin (A) may include only one type of the repeating unit (2-2), or may include two or more types of the repeating unit (2-2).

The content ratio of the repeating unit (2-2) in the resin (A) is preferably 5 to 75 mol %, more preferably 15 to 65 mol %, and particularly preferably 25 to 55 mol %. If the content ratio is less than 5 mol %, the resulting pattern may peel off due to insufficient adhesion to a substrate. On the other hand, if the content ratio exceeds 75 mol %, the pattern shape may deteriorate by impairing the contrast after dissolution.

### (3) Other Repeating Unit

The resin (A) may include the other repeating unit other than the repeating units (2-1) and (2-2). Specific examples of a polymerizable unsaturated monomers that produces the other repeating unit include alicyclic unsaturated compounds such as 5-fluorobicyclo[2.2.1]hept-2-ene, 5,5-difluorobicyclo[2.2.1]hept-2-ene, 8-fluorotetracyclo[6.2.1.1^{3,6}. 0^{2,7}] dodec-3-ene, 8,8-difluorotetracyclo[6.2.1.1^{3,6}.0^{2,7}]dodec-3-ene, dicyclopentadiene, and tricyclo[5.2.1.0^{2,6}]dec-8-ene;

(meth)acrylates such as methyl(meth)acrylate, ethyl(meth)acrylate, n-propyl(meth)acrylate, n-butyl(meth)acrylate, 2-hydroxyethyl(meth)acrylate, 2-hydroxypropyl(meth)acrylate, 3-hydroxypropyl(meth)acrylate, norbornyl(meth)acrylate, isobomyl(meth)acrylate, adamantyl(meth)acrylate, and adamantylmethyl(meth)acrylate; α-hydroxymethylacrylates such as methyl α-hydroxymethylacrylate and ethyl α-hydroxymethylacrylate;
vinyl esters such as vinyl acetate, vinyl propionate, and vinyl butyrate; unsaturated nitrile compounds such as (meth)acrylonitrile, α-chloro acrylonitrile, crotonitrile, and maleinitrile; unsaturated amide compounds such as (meth) acrylamide, N,N-dimethyl(meth)acrylamide, crotonamide, maleinamide, and fumaramide; other nitrogen-containing vinyl compounds such as N-vinyl-ε-caprolactam, N-vinylpyrrolidone, vinylpyridine, and vinylimidazole; unsaturated carboxylic acids (anhydrides) such as (meth)acrylic acid, crotonic acid, maleic acid, and maleic anhydride; carboxyl group-containing esters of unsaturated carboxylic acid such as 2-carboxyethyl(meth)acrylate, 2-carboxypropyl(meth)acrylate, and 3-carboxypropyl (meth)acrylate; and polyfunctional monomers such as methylene glycol di(meth)acrylate, ethylene glycol di(meth)acrylate, and propylene glycol di(meth)acrylate.

The resin (A) may be produced by copolymerizing corresponding polymerizable unsaturated monomers in an appropriate solvent optionally in the presence of a chain transfer agent using a radical initiator (e.g., hydroperoxide, dialkyl peroxide, diacyl peroxide, or azo compound), for example. Examples of the solvent include alkanes such as n-pentane, n-hexane, n-heptane, n-octane, n-nonane, and n-decane; cycloalkanes such as cyclohexane, cycloheptane, cyclooctane, decalin, and norbornane; aromatic hydrocarbons such as benzene, toluene, xylene, ethylbenzene, and cumene; halogenated hydrocarbons such as chlorobutanes, bromohexanes, dichloroethanes, hexamethylene dibromide, and chlorobenzene; saturated carboxylic acid esters such as ethyl acetate, n-butyl acetate, i-butyl acetate, and methyl propionate; ethers such as tetrahydrofuran, dimethoxyethane, and diethoxyethane; and the like. These solvents may be used either individually or in combination. The reaction temperature is normally 40 to 120° C., and preferably 50 to 90° C. The reaction time is normally 1 to 48 hours, and preferably 1 to 24 hours.

The polystyrene-reduced weight average molecular weight (hereinafter may be referred to as “Mw”) of the resin (A) determined by gel permeation chromatography (GPC) is normally 3000 to 300,000, preferably 4000 to 200,000, and still more preferably 4000 to 100,000. If the Mw is less than 3000, the heat resistance of the resist may deteriorate. If the Mw exceeds 300,000, the developability of the resist may deteriorate. It is preferable to keep the amount of the impurity such as halogens and metals in the resin (A) as low as possible. The sensitivity, the resolution, the process stability, the pattern shape, and the like of the resist can be further improved by reducing the amount of impurity in the resin (A). The resin (A) may be purified by chemical purification (e.g., washing with water or liquid-liquid extraction), or a combination of chemical purification and physical purification (e.g., ultrafiltration or centrifugation), for example. The radiation-sensitive resin composition may include only one type of the resin (A), or may include two or more types of the resin (A).

### 2. Acid Generating Agent (B)

The acid generating agent (B) generates an acid upon irradiation (application of radiation) (hereinafter may be referred to as “exposure”). The acid-labile group included in the resin (A) dissociates due to an acid generated by the acid generating agent (B), so that the resin (A) become alkali-soluble. As a result, the exposed area of the resist film becomes readily soluble in an alkaline developer, so that a positive type resist pattern can be formed. Examples of the acid generating agent (B) include onium salt compounds, halogen-containing compounds, diazoketone compounds, sulfone compounds, sulfonic acid compounds, and the like.

### (Onium Salt Compound)

Examples of the onium salt compounds include iodonium salts, sulfonium salts (including tetrahydrothiophenium salts), phosphonium salts, diazonium salts, pyridinium salts, and the like. Specific examples of the onium salt compounds include iodonium salts such as diphenyliodonium trifluoromethanesulfonate, diphenyliodonium nonafluoro-n-butanesulfonate, diphenyliodonium perfluoro-n-octanesulfonate, bis(4-t-butylphenyl)iodonium trifluoromethanesulfonate, bis(4-t-butylphenyl)iodonium nonafluoro-n-butanesulfonate, and bis(4-t-butylphenyl)iodonium perfluoro-n-octanesulfonate, sulfonium salts such as triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1-difluoroethanesulfonate, triphenylsulfonium 2-bicyclo[2.2.1]hept-2-yl-1,1,2,2-tetrafluoroethanesulfonate, triphenylsulfonium 1,1,2,2-tetrafluoro-6-(1-adamantane carbonyloxy)-hexane-1-sulfonate, triphenylsulfonium2-adamantyl-1,1-difluoroethanesulfonate, cyclohexyl•2-oxocyclohexyl•methylsulfonium trifluoromethanesulfonate, dicyclohexyl•2-oxocyclohexylsulfonium trifluoromethanesulfonate, 4-cyclohexylphenyl•diphenylsulfonium nonafluoro-n-butane sulfonate, 2-oxocyclohexyldimethylsulfonium trifluoromethanesulfonate, 1-naphthyldimethylsulfonium trifluoromethanesulfonate, 1-naphthyldiethylsulfonium trifluoromethanesulfonate, 4-cyano-1-naphthyldimethylsulfonium trifluoromethanesulfonate, 4-nitro-1-naphthyldimethylsulfonium trifluoromethanesulfonate, 4-methyl-1-naphthyldimethylsulfonium trifluoromethanesulfonate, and 4-hydroxy-1-naphthyldimethylsulfonium trifluoromethanesulfonate,

tetrahydrothiophenium salts such as 4-hydroxy-1-naphthyltetrahydrothiophenium trifluoromethanesulfonate, 4-hydroxy-1-naphthyltetrahydrothiophenium nonafluoro-n-butanesulfonate, 4-hydroxy-1-naphthyltetrahydro thiopheniumperfluoro-n-octanesulfonate, 4-methoxy-1-naphthyltetrahydrothiophenium trifluoromethanesulfonate, 4-methoxy-1-naphthyltetrahydrothiophenium nonafluoro-n-butanesulfonate, 4-(1-methoxyethoxy)-1-naphthyltetrahydrothiophenium trifluoromethanesulfonate, 4-(1-methoxyethoxy)-1-naphthyltetrahydrothiophenium nonafluoro-n-butanesulfonate, 4-methoxycarbonyloxy-1-naphthyltetrahydrothiophenium trifluoromethanesulfonate, 4-methoxycarbonyloxy-1-naphthyltetrahydrothiophenium nonafluoro-n-butanesulfonate,
4-(2-tetrahydrofuranyloxy)-1-naphthyltetrahydrothiophenium trifluoromethanesulfonate, 4-(2-tetrahydrofuranyloxy)-1-naphthyltetrahydrothiophenium nonafluoro-n-butanesulfonate, 4-benzyloxy-1-naphthyltetrahydrothiophenium trifluoromethanesulfonate, 4-benzyloxy-1-naphthyltetrahydrothiophenium nonafluoro-n-butanesulfonate, 1-(1-naphthylacetomethyl)tetrahydrothiophenium trifluoromethanesulfonate, 1-(1-naphthylacetomethyl)tetrahydrothiophenium nonafluoro-n-butanesulfonate, 1-(1-naphthylacetomethyl)tetrahydrothiophenium perfluoro-n-octanesulfonate, 1-(3,5-dimethyl-4-hydroxyphenyl)tetrahydrothiophenium trifluoromethanesulfonate, 1-(3,5-dimethyl-4-hydroxyphenyl)tetrahydrothiophenium nonafluoro-n-butanesulfonate, and 1-(3,5-dimethyl-4-hydroxyphenyl)tetrahydrothiophenium perfluoro-n-octanesulfonate, and the like.
(Halogen-containing compound)

Examples of the halogen-containing compounds include haloalkyl group-containing hydrocarbon compounds, haloalkyl group-containing heterocyclic compounds, and the like. Specific examples of the halogen-containing compounds include (trichloromethyl)-s-triazine derivatives such as phenylbis(trichloromethyl)-s-triazine, 4-methoxyphenylbis(trichloromethyl)-s-triazine, and 1-naphthylbis(trichloromethyl)-s-triazine, 1,1-bis(4-chlorophenyl)-2,2,2-trichloroethane, and the like.

### (Diazoketone Compound)

Examples of the diazoketone compounds include 1,3-diketo-2-diazo compounds, diazobenzoquinone compounds, diazonaphthoquinone compounds, and the like. Specific examples of the diazoketone compounds include 1,2-naphthoquinonediazide-4-sulfonyl chloride, 1,2-naphthoquinonediazide-5-sulfonyl chloride, 1,2-naphthoquinonediazide-4-sulfonate or 1,2-naphthoquinonediazide-5-sulfonate of 2,3,4,4′-tetrahydroxybenzophenone, 1,2-naphthoquinonediazide-4-sulfonate or 1,2-naphthoquinonediazide-5-sulfonate of 1,1,1-tris(4-hydroxyphenyl)ethane, and the like.

### (Sulfone Compound)

Examples of the sulfone compounds include β-ketosulfones, β-sulfonylsulfones, α-diazo compounds of these compounds, and the like. Specific examples of the sulfone compounds include 4-trisphenacylsulfone, mesitylphenacylsulfone, bis(phenylsulfonyl)methane, and the like.

### (Sulfonic Acid Compound)

Examples of the sulfonic acid compounds include alkyl sulfonates, alkylimide sulfonates, haloalkyl sulfonates, aryl sulfonates, imino sulfonates, and the like. Specific examples of the sulfonic acid compounds include benzointosylate, tris(trifluoromethanesulfonate) of pyrogallol, nitrobenzyl-9,10-diethoxyanthracene-2-sulfonate, trifluoromethanesulfonylbicyclo[2.2.1]hept-5-ene-2,3-dicarbodiimide, nonafluoro-n-butanesulfonylbicyclo[2.2.1]hept-5-ene-2,3-dicarbodiimide, perfluoro-n-octanesulfonylbicyclo[2.2.1]%ept-5-ene-2,3-dicarbodiimide, N-hydroxysuccinimidetrifluoromethanesulfonate, N-hydroxysuccinimidenonafluoro-n-butanesulfonate, N-hydroxysuccinimideperfluoro-n-octanesulfonate, 1,8-naphthalenedicarboxylic acid imide trifluoromethanesulfonate, and the like.

Among these acid generating agent (B), diphenyliodonium trifluoromethanesulfonate, diphenyliodonium nonafluoro-n-butanesulfonate, diphenyliodonium perfluoro-n-octanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1-difluoroethanesulfonate, triphenylsulfonium 2-bicyclo[2.2.1]hept-2-yl-1,1,2,2-tetrafluoroethanesulfonate, triphenylsulfonium 1,1,2,2-tetrafluoro-6-(1-adamantanecarbonyloxy)-hexane-1-sulfonate, triphenylsulfonium 2-adamantyl-1,1-difluoroethanesulfonate, cyclohexyl•2-oxocyclohexyl•methylsulfonium trifluoromethanesulfonate, dicyclohexyl•2-oxocyclohexylsulfonium trifluoromethanesulfonate, 4-cyclohexylphenyl•diphenylsulfonium nonafluoro-n-butanesulfonate, 2-oxocyclohexyldimethylsulfonium trifluoromethanesulfonate, 4-hydroxy-1-naphthyldimethylsulfonium trifluoromethanesulfonate,

4-hydroxy-1-naphthyltetrahydrothiophenium trifluoromethanesulfonate, 4-hydroxy-1-naphthyltetrahydrothiophenium nonafluoro-n-butanesulfonate, 4-hydroxy-1-naphthyltetrahydrothiophenium perfluoro-n-octanesulfonate, 1-(1-naphthylacetomethyl)tetrahydrothiophenium trifluoromethanesulfonate, 1-(1-naphthylacetomethyl)tetrahydrothiophenium nonafluoro-n-butanesulfonate, 1-(1-naphthylacetomethyl)tetrahydrothiophenium perfluoro-n-octanesulfonate, 1-(3,5-dimethyl-4-hydroxyphenyl)tetrahydrothiophenium trifluoromethanesulfonate, 1-(3,5-dimethyl-4-hydroxyphenyl)tetrahydrothiophenium nonafluoro-n-butanesulfonate, 1-(3,5-dimethyl-4-hydroxyphenyl)tetrahydrothiophenium perfluoro-n-octanesulfonate,
trifluoromethanesulfonylbicyclo[2.2.1]hept-5-ene-2,3-dicarbodiimide, nonafluoro-n-butanesulfonylbicyclo [2.2.1]hept-5-ene-2,3-dicarbodiimide, perfluoro-n-octanesulfonylbicyclo[2.2.1]hept-5-ene-2,3-dicarbodiimide, N-hydroxysuccinimidetrifluoromethanesulfonate, N-hydroxysuccinimidenonafluoro-n-butanesulfonate, N-hydroxysuccinimideperfluoro-n-octanesulfonate, 1,8-naphthalenedicarboxylic acid imide trifluoromethanesulfonate, and the like are preferable.

The radiation-sensitive resin composition of the embodiment of the present invention may include only one type of the acid generating agent (B), or may include two or more types of the acid generating agent (B). The amount of the acid generating agent (B) is normally 0.1 to 30 parts by mass, preferably 2 to 27 parts by mass, and still more preferably 5 to 25 parts by mass, based on 100 parts by mass of the resin (A). If the amount is less than 0.1 parts by mass, the sensitivity and the resolution as the resist may deteriorate. On the other hand, if the amount exceeds 30 parts by mass, the applicability as the resist and the pattern shape may deteriorate.

### 3. Acid Diffusion Controller (C)

The acid diffusion controller (C) includes the compound (C1) and the compound (C2). The amount of the acid diffusion controller (C) is normally 0.001 to 15 parts by mass, preferably 0.005 to 10 parts by mass, and still more preferably 0.01 to 5 parts by mass, based on 100 parts by mass of the resin (A). If the amount is less than 0.001 parts by mass, the resolution as the resist and the pattern shape may deteriorate. On the other hand, if the amount exceeds 15 parts by mass, the sensitivity and the developability as the resist may deteriorate.

### (1) Compound (C1)

The compound (C1) is shown by the general formula (1-1). Since the radiation-sensitive resin composition includes the compound (C1), a phenomenon in which an acid generated by the acid generating agent (B) upon exposure is diffused in the resist film can be controlled. In addition, since the compound (C1) is deprotected by an acid, the alkali-solubility of the resist surface can be improved, so that occurrence of a T-top shape can be suppressed.

Examples of the cycloalkyl group represented by R¹ and R² in the general formula (1-1) include monocyclic and polycyclic monovalent alicyclic hydrocarbon groups. Specific examples of the cycloalkyl group represented by R¹ and R² in the general formula (1-1) include monocyclic saturated hydrocarbon groups such as a cyclopropyl group, a cyclobutyl group, a cyclopentyl group, a cyclohexyl group, a cycloheptyl group, a cyclooctyl group, a cyclodecyl group, a methylcyclohexyl group, and an ethylcyclohexyl group, and polycyclic saturated hydrocarbon groups such as a bicyclo[2.2.1]heptyl group, a bicyclo[2.2.2]octyl group, a tricyclo[5.2.1.0^{2,6}]decyl group, a tricyclo[3.3.1.1^{3,7}]decyl group, a tetracyclo[6.2.1.1^{3,6}.0^{2,7}]dodecyl group, and an adamantyl group.

Examples of a substituent that may substitute R¹ and R² include an alkoxy group having 1 to 10 carbon atoms, an acyl group having 2 to 11 carbon atoms, an acyloxy group having 2 to 11 carbon atoms, a hydroxyl group, a nitro group, a cyano group, and the like. Examples of the substituted or unsubstituted heterocyclic hydrocarbon group having 1 to 20 atoms formed by R¹ and R² together with the nitrogen atom bonded to R¹ and R² include heterocyclic aliphatic hydrocarbon groups and heterocyclic aromatic hydrocarbon groups. Among these, heterocyclic aliphatic hydrocarbon groups are preferable.

Specific examples of the acid-labile group represented by R^{p} in the general formula (1-1) include a group shown by the following general formula (1-1-1).

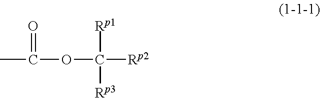

wherein R^{p1} to R^{p3} individually represent a linear or branched alkyl group having 1 to 4 carbon atoms or a monovalent alicyclic hydrocarbon group having 4 to 20 carbon atoms, provided that R^{p2} and R^{p3} may bond to each other to form an alicyclic hydrocarbon group having 4 to 20 carbon atoms together with the carbon atom bonded to R^{p2} and R^{p3}, and R^{p1} may represent a linear or branched alkyl group having 1 to 4 carbon atoms or a monovalent alicyclic hydrocarbon group having 4 to 20 carbon atoms.

Examples of the alkyl group having 1 to 4 carbon atoms or the monovalent alicyclic hydrocarbon group having 4 to 20 carbon atoms represented by R^{p1} to R^{p3} in the general formula (1-1-1), and the divalent alicyclic hydrocarbon group having 4 to 20 carbon atoms formed by R^{p2} and R^{p3} together with the carbon atom bonded to R^{p2} and R^{p3}, include those mentioned above in connection with R⁸ to R¹⁰ in the general formula (i). Specific examples of the group —C(R^{p1}, R^{p2}, R^{p3}) in the general formula (1-1-1) include tertiary alkyl groups such as a t-butyl group and a t-amyl group; monocyclic hydrocarbon groups such as a 1-methyl-1-cyclopentyl group and a 2-ethyl-1-cyclopentyl group, polycyclic hydrocarbon groups such as a 2-methyl-2-adamantyl group and a 2-ethyl-2-adamantyl group; a t-butylcyclohexyl group, a t-butylnorbornyl group, a t-butyladamantyl group, and the like.

Specific examples of the compound shown by the general formula (1-1) include compounds shown by the following general formulas (1-11) to (1-17). Among these, the compounds shown by the general formulas (1-11) to (1-14) are preferable. Note that R′ in the general formulas (1-11) to (1-17) represents an alkyl group having 8 to 10 carbon atoms, and R^{p} represents an acid-labile group. R′ preferably represents an n-alkyl group having 8 to 10 carbon atoms.

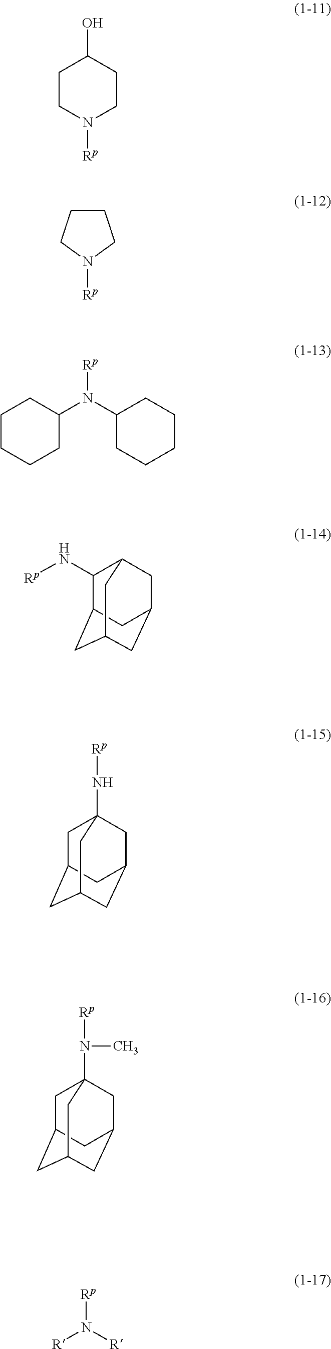

Further specific examples of the compound shown by the general formula (1-1) include compounds shown by the following general formulas (1-1a) to (1-1d). Among these, the compound shown by the general formula (1-1a) is particularly preferable from the viewpoint of the reactivity of the acid-labile group.

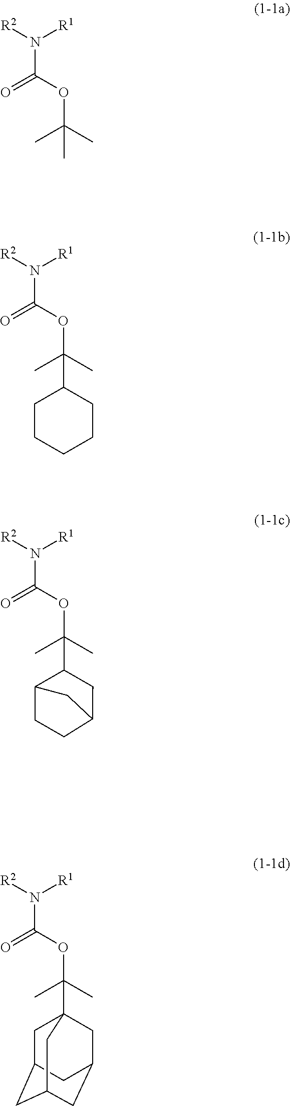

wherein R¹ and R² individually represent a hydrogen atom, a linear or branched alkyl group, a cycloalkyl group, an aryl group, or an aralkyl group, provided that R¹ and R² may bond to each other to form a substituted or unsubstituted heterocyclic hydrocarbon group having 1 to 20 atoms together with the nitrogen atom bonded to R¹ and R².

Specific examples of the compound (C1) include N-t-butoxycarbonyl-4-hydroxypiperidine, N-t-butoxycarbonylpyrrolidine, N-t-butoxycarbonyl-dicyclohexylamine, N-t-butoxycarbonyl-2-adamantylamine, N-t-butoxycarbonyldi-n-octylamine, N-t-butoxycarbonyldi-n-nonylamine, N-t-butoxycarbonyldi-n-decylamine, N-t-butoxycarbonyl-1-adamantylamine, N-t-butoxycarbonyl-N-methyl-1-adamantylamine, N,N′-di-t-butoxycarbonyl-4,4′-diaminodiphenyl methane, and the like. Among these, N-t-butoxycarbonyl-4-hydroxypiperidine, N-t-butoxycarbonylpyrrolidine, N-t-butoxycarbonyl-dicyclohexylamine, and N-t-butoxycarbonyl-2-adamantylamine are preferable.

### (2) Compound (C2)

The compound (C2) is shown by the general formula (1-2) or (1-3). Since the compound (C2) exhibits high basicity as compared with the compound (C1), a phenomenon in which an acid generated by the acid generating agent (B) upon exposure is diffused in the resist film can be controlled more efficiently. As s result, the resolution as the resist is further improved.

Examples of a substituent that may substitute R³ to R⁶ in the general formula (1-2) or (1-3) include those mentioned above in connection with R¹ and R² in the general formula (1-1).

Specific examples of the compound (C2) include imidazole, benzimidazole, 2-methylimidazole, 4-methylimidazole, 2-phenylimidazole, 4-phenylimidazole, 2-phenyl-4-methylimidazole, 2-methyl-4-phenylimidazole, 1-(3-hydroxypropyl)-2-phenylbenzimidazole, 2,4,5-triphenylimidazole, 2-methylbenzimidazol, 2-phenylbenzimidazole, 5-nitrobenzimidazole, and the like. Among these, 2-phenylbenzimidazole, 1-(3-hydroxypropyl)-2-phenylbenzimidazole, 2,4,5-triphenylimidazole, and 5-nitrobenzimidazole are preferable.

The content ratio (compound (C1)/compound (C2)) of the compound (C1) to the compound (C2) is preferably 99/1 to 1/99 parts by mass, more preferably 90/10 to 10/90 parts by mass, and particularly preferably 75/25 to 25/75 parts by mass, based on 100 parts by mass of the compound (C1) and the compound (C2) in total (i.e., acid diffusion controller (C)). If the content ratio of the compound (C1) exceeds 99 parts by mass (i.e., the content ratio of the compound (C2) is less than 1 part by mass), the sensitivity as the resist may deteriorate. On the other hand, if the content ratio of the compound (C1) is less than 1 part by mass (i.e., the content ratio of the compound (C2) exceeds 99 parts by mass), the alkali developability of the resist surface may be insufficient, so that a T-top shape may occur.

### 4. Polymer (D)

The radiation-sensitive resin composition according to one embodiment of the present invention preferably further includes the polymer (D). When the radiation-sensitive resin composition includes the polymer (D), it is unnecessary to form an upper-layer film that separates a photoresist film and an immersion medium when using the radiation-sensitive resin composition for liquid immersion lithography. Therefore, the radiation-sensitive resin composition can suitably be used for liquid immersion lithography.

The polymer (D) is not particularly limited as long as the one including a fluorine atom in the molecule. It is preferable that the polymer (D) include a repeating unit including a fluorine atom (hereinafter may be referred to as “repeating unit (D1)”). Specific example of the repeating unit (D1) include a repeating unit shown by the following general formula (D1-1) (hereinafter may be referred to as “repeating unit (D1-1)”) and a repeating unit shown by the following general formula (D1-2) (hereinafter may be referred to as “repeating unit (D1-2)”).

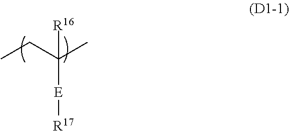

wherein R¹⁶ represents a hydrogen atom, a methyl group, or a trifluoromethyl group, E represents a linking group, and R¹⁷ represents a linear or branched alkyl group having 1 to 6 carbon atoms that is substituted with at least one fluorine atom, or a monovalent alicyclic hydrocarbon group having 4 to 20 carbon atoms that is substituted with at least one fluorine atom.

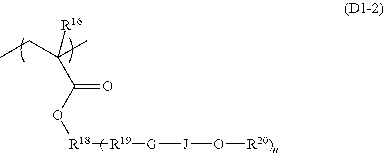

wherein R¹⁶ represents a hydrogen atom, a methyl group, or a trifluoromethyl group, R¹⁸ represents a single bond or a linear, branched, or cyclic saturated or unsaturated (n+1)-valent hydrocarbon group having 1 to 10 carbon atoms, R¹⁹ represents a single bond or a linear, branched, or cyclic saturated or unsaturated divalent hydrocarbon group having 1 to 20 carbon atoms, G represents a methylene group substituted with a fluorine atom, or a linear or branched fluoroalkylene group having 2 to 20 carbon atoms, J represents a single bond or —CO—, n is an integer from 1 to 3, and R²⁰ represents a hydrogen atom or an acid-labile group, provided that R¹⁹, G, J, and R²⁰ may respectively be either the same or different when n is 2 or 3.

E in the general formula (D1-1) represents a linking group. Examples of the linking group include a single bond, an oxygen atom, a sulfur atom, a carbonyloxy group, an oxycarbonyl group, an amide group, a sulfonylamide group, a urethane group, and the like.

Examples of the linear or branched alkyl group having 1 to 6 carbon atoms that is substituted with at least one fluorine atom represented by R¹⁷ in the general formula (D1-1) include groups obtained by partial fluorination of a linear or branched alkyl group (e.g., methyl group, ethyl group, 1-propyl group, 2-propyl group, 1-butyl group, 2-butyl group, 2-(2-methylpropyl) group, 1-pentyl group, 2-pentyl group, 3-pentyl group, 1-(2-methylbutyl) group, 1-(3-methylbutyl) group, 2-(2-methylbutyl) group, 2-(3-methylbutyl) group, neopentyl group, 1-hexyl group, 2-hexyl group, 3-hexyl group, 1-(2-methylpentyl) group, 1-(3-methylpentyl) group, 1-(4-methylpentyl) group, 2-(2-methylpentyl) group, 2-(3-methylpentyl) group, 2-(4-methylpentyl) group, 3-(2-methylpentyl) group, or 3-(3-methylpentyl) group), a perfluoroalkyl group, and the like.

Examples of the monovalent alicyclic hydrocarbon group having 4 to 20 carbon atoms that is substituted with at least one fluorine atom include groups obtained by partial fluorination of an alicyclic alkyl group (e.g., cyclopentyl group, cyclopentylmethyl group, 1-(1-cyclopentylethyl) group, 1-(2-cyclopentylethyl) group, cyclohexyl group, cyclohexylmethyl group, 1-(1-cyclohexylethyl) group, 1-(2-cyclohexylethyl) group, cycloheptyl group, cycloheptylmethyl group, 1-(1-cycloheptylethyl) group, 1-(2-cycloheptylethyl) group, or 2-norbornyl group), a perfluoroalkyl group, and the like.

Examples of a preferable monomer that produces the repeating unit (D1-1) include trifluoromethyl(meth)acrylate, 2,2,2-trifluoroethyl(meth)acrylate, perfluoroethyl (meth)acrylate, perfluoro-n-propyl(meth)acrylate, perfluoro-1-propyl(meth)acrylate, perfluoro-n-butyl(meth)acrylate, perfluoro-1-butyl(meth)acrylate, perfluoro-t-butyl (meth)acrylate, 2-(1,1,1,3,3,3-hexafluoropropyl) (meth)acrylate, 1-(2,2,3,3,4,4,5,5-octafluoropentyl) (meth)acrylate, perfluorocyclohexylmethyl (meth)acrylate, 1-(2,2,3,3,3-pentafluoropropyl) (meth)acrylate, and the like.

Examples of the linear or branched saturated or unsaturated (n+1)-valent hydrocarbon group having 1 to 10 carbon atoms represented by R¹⁸ in the general formula (D1-2) include divalent hydrocarbon groups derived from a linear or branched alkyl group having 1 to 10 carbon atoms (e.g., methyl group, ethyl group, n-propyl group, i-propyl group, n-butyl group, 2-methylpropyl group, 1-methylpropyl group, t-butyl group, pentyl group, isopentyl group, neopentyl group, hexyl group, heptyl group, octyl group, nonyl group, or decyl group), and the like.

Examples of the cyclic saturated or unsaturated (n+1)-valent hydrocarbon group include groups derived from an alicyclic hydrocarbon having 3 to 10 carbon atoms or an aromatic hydrocarbon. Examples of the alicyclic hydrocarbon include cycloalkanes such as cyclobutane, cyclopentane, cyclohexane, bicyclo[2.2.1]heptane, bicyclo[2.2.2]octane, tricyclo[5.2.1.0^{2,6}]decane, and tricyclo[3.3.1.1^{3,7}]decane, and the like. Examples of the aromatic hydrocarbon include benzene, naphthalene, and the like.

Examples of the linear or branched saturated or unsaturated divalent hydrocarbon group having 1 to 20 carbon atoms represented by R¹⁹ in the general formula (D1-2) include divalent hydrocarbon groups derived from a linear or branched alkylene group having 1 to 20 carbon atoms (e.g., methylene group, ethylene group, trimethylene group, 1,2-propylene group, tetramethylene group, 2-methyl-1,3-propylene group, 1-methyl-1,3-propylene group, 2,2-dimethyl-1,3-propylene group, pentamethylene group, 2-methyl-1,3-butylene group, hexamethylene group, heptamethylene group, octamethylene group, nonamethylene group, or decamethylene group), and the like.

Examples of the cyclic saturated or unsaturated divalent hydrocarbon group include groups derived from an alicyclic hydrocarbon having 3 to 20 carbon atoms or an aromatic hydrocarbon. Specific examples of the alicyclic hydrocarbon include cycloalkanes such as cyclobutane, cyclopentane, cyclohexane, bicyclo[2.2.1]heptane, bicyclo[2.2.2]octane, tricyclo[5.2.1.0^{2,6}]decane, tricyclo[3.3.1.1^{3,7}]decane, and tetracyclo[6.2.1.1^{3,6}.0^{2,7}]dodecane, and the like. Specific examples of the aromatic hydrocarbon include benzene, naphthalene, and the like.

The hydrocarbon group represented by R¹⁹ in the general formula (D1-2) may be a group obtained by substituting at least one hydrogen atom of the above unsubstituted hydrocarbon group with at least one of a linear or branched alkyl group having 1 to 12 carbon atoms such as a methyl group, an ethyl group, an n-propyl group, an i-propyl group, an n-butyl group, a 2-methylpropyl group, a 1-methylpropyl group, or a t-butyl group, a cycloalkyl group, a hydroxyl group, a cyano group, a hydroxyalkyl group having 1 to 10 carbon atoms, a carboxyl group, an oxygen atom, and the like.

The acid-labile group represented by R²⁰ in the general formula (D1-2) means a group that substitutes a hydrogen atom of an acidic functional group such as a hydroxyl group, a carboxyl group, or a sulfonic acid group, and dissociates in the presence of an acid. Specific examples of the acid-labile group include a t-butoxycarbonyl group, a tetrahydropyranyl group, a tetrahydrofuranyl group, a (thiotetrahydropyranylsulfanyl)methyl group, a (thiotetrahydrofuranylsulfanyl)methyl group, an alkoxy-substituted methyl group, an alkylsulfanyl-substituted methyl group, and the like. Examples of the alkoxy group (substituent) of the alkoxy-substituted methyl group include alkoxy groups having 1 to 4 carbon atoms. Examples of the alkyl group (substituent) of the alkylsulfanyl-substituted methyl group include alkyl groups having 1 to 4 carbon atoms. The acid-labile group may be the group shown by the general formula (1) described above in the section entitled “1. Resin (A)”.

Examples of the methylene group substituted with a fluorine atom or the linear or branched fluoroalkylene group having 2 to 20 carbon atoms represented by G in the general formula (D1-2) include the groups shown by the following formulas (X-1) to (X-8), and the like.

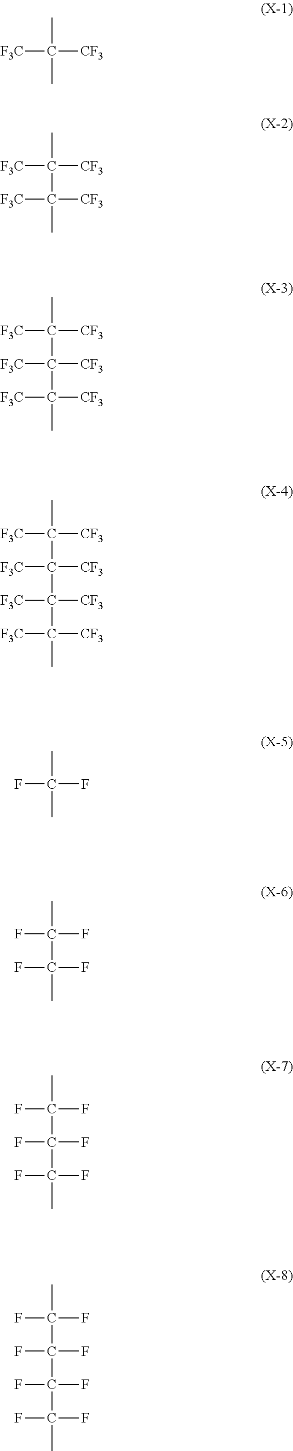

Specific examples of the repeating unit (D1-2) include repeating units shown by the following general formulas (D1-2-1) to (D1-2-3).

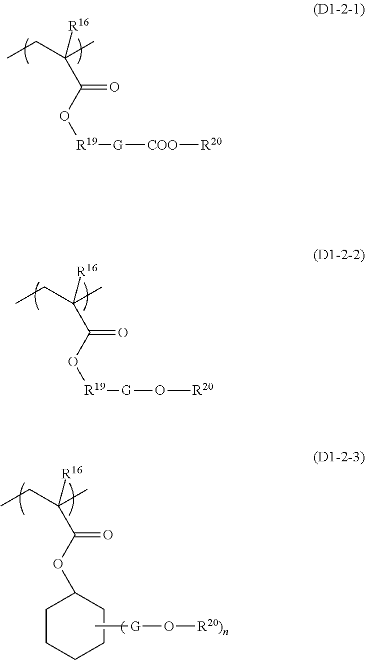

wherein R¹⁶ represents a hydrogen atom, a methyl group, or a trifluoromethyl group, G represents a methylene group substituted with a fluorine atom, or a linear or branched fluoroalkylene group having 2 to 20 carbon atoms, R²⁰ represents a hydrogen atom or an acid-labile group, R¹⁹ represents a single bond or a linear, branched, or cyclic saturated or unsaturated divalent hydrocarbon group having 1 to 20 carbon atoms, and n is an integer from 1 to 3, provided that G and R²⁰ may respectively be either the same or different when n is 2 or 3.

Specific examples of a monomer that produces the repeating unit (D1-2) include compounds shown by the following general formulas (M−1) to (M-6). Note that R¹⁶ in the general formulas (M−1) to (M-6) represents a hydrogen atom, a methyl group, or a trifluoromethyl group, and R²⁰ represents a hydrogen atom or an acid-labile group.

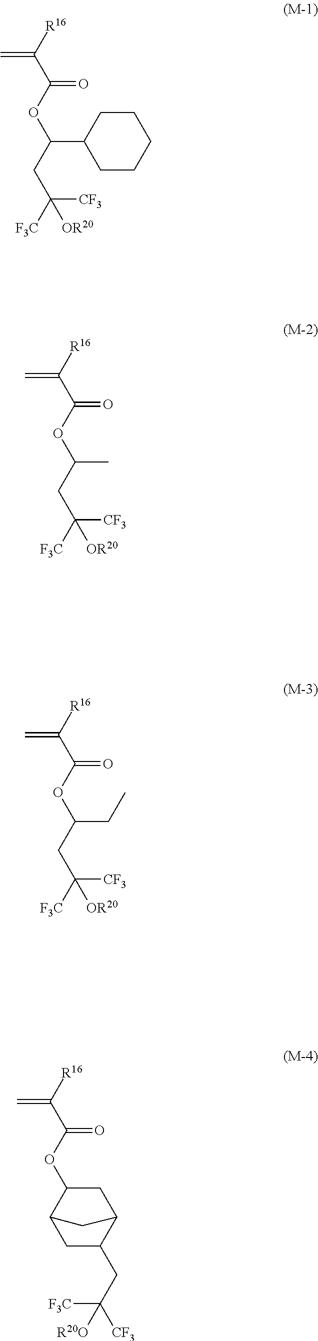

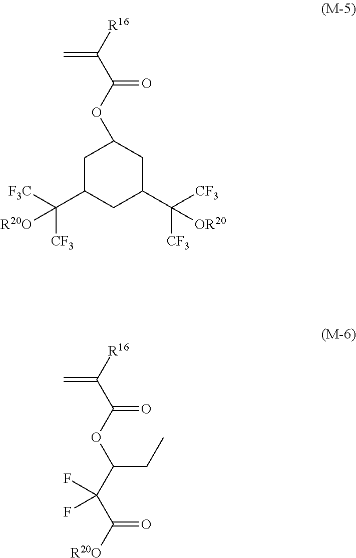

The polymer (D) may further include a repeating unit having an acid-labile group and not falling under the repeating unit (D1) (hereinafter may be referred to as “repeating unit (D2)”), a repeating unit having an alkali-soluble group and not falling under the repeating unit (D1) (hereinafter may be referred to as “repeating unit (D3)”), and/or a repeating unit having an alkali-reactive group and not falling under the repeating unit (D1) (hereinafter may be referred to as “repeating unit (D4)”), in addition to the repeating unit (D1).

When the polymer (D) includes the repeating unit (D2), the difference between the advancing contact angle and the receding contact angle of the resist film can be reduced, so that it can cope with the improvement in the scan speed during exposure. A repeating unit shown by the following general formula (D2-1) is preferable as the repeating unit (D2).

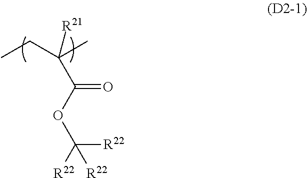

wherein R²¹ represents a hydrogen atom, a methyl group, a trifluoromethyl group, or a hydroxymethyl group, and R²² individually represent a linear or branched alkyl group having 1 to 4 carbon atoms or a monovalent alicyclic hydrocarbon group having 4 to 20 carbon atoms, provided that two of R²² may bond to each other to form a divalent alicyclic hydrocarbon group having 4 to 20 carbon atoms together with the carbon atom bonded to the two R²², and the remaining R²² may represent a linear or branched alkyl group having 1 to 4 carbon atoms or a monovalent alicyclic hydrocarbon group having 4 to 20 carbon atoms.

The description given above in connection with R⁸ to R¹⁰ in the general formula (1) in the section entitled “1. Resin (A)” may be applied to R²² in the general formula (D2-1).

Among the general formula (D2-1), a repeating unit shown by the following general formula (D2-1-1) is particularly preferable as the repeating unit (D2).

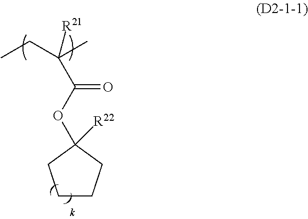

wherein R²¹ represents a hydrogen atom, a methyl group, a trifluoromethyl group, or a hydroxymethyl group, R²² represents a linear or branched alkyl group having 1 to 4 carbon atoms, and k is an integer from 1 to 4.

Examples of the linear or branched alkyl group having 1 to 4 carbon atoms represented by R²² in the general formula (D2-1-1) include a methyl group, an ethyl group, an n-propyl group, an i-propyl group, an n-butyl group, a 2-methylpropyl group, a 1-methylpropyl group, a t-butyl group, and the like.

The polymer (D) may include only one type of the repeating unit (D2), or may include two or more types of the repeating unit (D2). The polymer (D) may further include the repeating unit (D3) or (D4) in addition to the repeating units (D1) and (D2). In this case, the solubility in a developer can be improved.

The alkali-soluble group included in the repeating unit (D3) is preferably a functional group having a hydrogen atom of which pKa is 4 to 11. This is from the view point of improving the solubility in a developer can be improved. Specific examples of such a functional group include functional groups shown by the following general formulas (D3a) and (D3b). Note that R²³ in the general formula (D3a) represents a hydrocarbon group having 1 to 10 carbon atoms that is substituted with a fluorine atom.

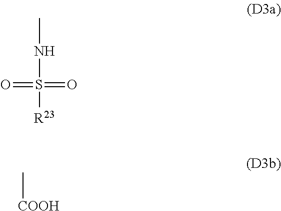

The hydrocarbon group having 1 to 10 carbon atoms that is substituted with a fluorine atom represented by R²³ in the general formula (D3a) is not particularly limited as long as the one obtained by substituting one or more hydrogen atoms of a hydrocarbon group having 1 to 10 carbon atoms with a fluorine atom, and is preferably a trifluoromethyl group or the like.

The main chain skeleton of the repeating unit (D3) is not particularly limited, and is preferably a methacrylate skeleton, an acrylate skeleton, an α-trifluoroacrylate skeleton, or the like.

Examples of the repeating unit (D3) include repeating units derived from compounds shown by the following general formulas (D3a-1) and (D3b-1).

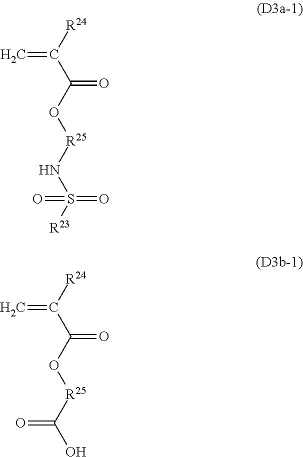

wherein R²⁴ represents a hydrogen atom, a methyl group, or a trifluoromethyl group, R²⁵ represents a single bond or a linear, branched, or cyclic saturated or unsaturated divalent hydrocarbon group having 1 to 20 carbon atoms, and R²³ represents a hydrocarbon group having 1 to 10 carbon atoms that is substituted with a fluorine atom.

Examples of the group represented by R²⁵ in the general formulas (D3a-1) and (D3b-1) include those mentioned above in connection with R¹⁷ in the general formula (D1-1). Examples of the group represented by R²³ in the general formula (D3a-1) include those mentioned above in connection with R²³ in the general formula (D3a).

The polymer (D) may include only one type of the repeating unit (D3), or may include two or more types of the repeating unit (D3).

Specific example of the repeating unit (D4) include a repeating unit having a lactone skeleton (hereinafter may be referred to as “repeating unit (D4-1)”) and a repeating unit having a cyclic carbonate structure (hereinafter may be referred to as “repeating unit (D4-2)”). Examples of the repeating unit (D4-1) include repeating units derived from the compound shown by the general formulas (2-2-1a) to (2-2-1f) above mentioned “Repeating unit (2-2)”. Examples of the repeating unit (D4-2) include the repeating unit shown by the general formula (2-2-2).

The content ratio of each repeating unit based on the total content (=100 mol %) of the repeating units included in the polymer (D) is preferably as follows. The content ratio of the repeating unit (D1) is preferably 20 to 90 mol %, more preferably 20 to 80 mol %, and particularly preferably 20 to 70 mol %. If the content ratio is within the above range, it is especially effective from view point of achieving a good balance between the securement of water repellency after application and increasing the contact angle with a developer after PEB.

Moreover, the content ratio of the repeating unit (D2) is preferably 80 mol % or less, more preferably 20 to 80 mol %, and particularly preferably 30 to 70 mol %. If the content ratio of the repeating unit (D2) is within the above range, the difference between the advancing contact angle and the receding contact angle can be reduced. Further, the content ratio of the repeating unit (D3) is preferably 50 mol % or less, more preferably 5 to 30 mol %, and particularly preferably 5 to 20 mol %. If the content ratio of the repeating unit (D3) is within the above range, it is especially effective from view point of achieving a good balance between the securement of water repellency after application and increasing the contact angle with a developer after PEB.

In addition, the content ratio of the repeating unit (D4) is preferably 50 mol % or less, more preferably 5 to 30 mol %, and particularly preferably 5 to 20 mol %. If the content ratio of the repeating unit (D4) is within the above range, it is especially effective from view point of achieving a good balance between the securement of water repellency after application and increasing the contact angle with a developer after PEB.

The polymer (D) may be produced by polymerizing a polymerizable unsaturated monomer that corresponds to each repeating unit in an appropriate solvent optionally in the presence of a chain transfer agent using a radical initiator such as a hydroperoxide, a dialkyl peroxide, a diacyl peroxide, or an azo compound.

The Mw of the polymer (D) is preferably 1000 to 50,000, more preferably 1000 to 40,000, and particularly preferably 1000 to 30,000. If the Mw is less than 1000, a resist film that has a sufficient receding contact angle may not be obtained. On the other hand, if the Mw exceeds 50,000, the developability of the resist film may deteriorate. The ratio (Mw/Mn) of the Mw to the polystyrene-reduced number average molecular weight (hereinafter may be referred to as “Mn”) of the polymer (D) determined by GPC is preferably 1 to 5, and more preferably 1 to 4.

It is preferable to keep the amount of the impurity (e.g., halogen and metal) in the polymer (D) as low as possible. The sensitivity, the resolution, the process stability, the pattern shape, and the like of the resist film can be further improved by reducing the amount of the impurity in the polymer (D).

The amount of the polymer (D) is preferably 0.1 to 20 parts by mass, more preferably 1 to 10 parts by mass, and particularly preferably 1 to 7.5 parts by mass, based on 100 parts by mass of the resin (A). If the amount is less than 0.1 parts by mass, a sufficient effect obtained by containing the polymer (D) may not be achieved. On the other hand, if the amount exceeds 20 parts by mass, development defect may occur by increasing the water repellency of the resist surface too much.

### 5. Additives

The radiation-sensitive resin composition according to one embodiment of the present invention may optionally include an additive such as an acid diffusion controller other than the acid diffusion controller (C) (hereinafter may be referred to as “other acid diffusion controller”), an alicyclic additive, and a surfactant. Examples of the other acid diffusion controller include monoalkylamines such as n-hexylamine and n-heptylamine, dialkylamines such as di-n-butylamine and di-n-pentylamine, trialkylamines such as triethylamine and tri-n-propylamine, aromatic amines such as aniline and N-methylaniline,

compounds having two nitrogen atoms in one molecule, such as ethylenediamine and N,N,N′,N′-tetramethylethylenediamine, compounds having three or more nitrogen atoms in one molecule, such as polyethylenimine and polyallylamine, amide group-containing compounds such as formamide and N-methylformamide, urea compounds such as urea and methylurea, and nitrogen-containing heterocyclic compounds such as pyridine and 2-methylpyridine.

These other acid diffusion controllers may be used either individually or in combination. The content ratio of the other acid diffusion controller is normally 90 mass % or less, preferably 70 mass % or less, and still more preferably 50 mass % or less, based on the total content of the acid diffusion controller (C) and the other acid diffusion controller. If the content ratio of the other acid diffusion controller exceeds 90 mass %, the intended effects of the present invention may be impaired.

The alicyclic additive further improves the dry etching resistance, the pattern shape, adhesion to a substrate, and the like. Examples of the alicyclic additive include adamantane derivatives such as t-butyl 1-adamantanecarboxylate and t-butoxycarbonylmethyl 1-adamantanecarboxylate; deoxycholates such as t-butyl deoxycholate and t-butoxycarbonylmethyl deoxycholate; lithocholates such as t-butyl lithocholate and t-butoxycarbonylmethyl lithocholate, and the like. These alicyclic additives may be used either individually or in combination. The amount of the alicyclic additive is normally 50 parts by mass or less, and preferably 30 parts by mass or less, based on 100 parts by mass of the resin (A). If the amount of the alicyclic additive exceeds 50 parts by mass, the heat resistance as the resist may deteriorate.

The surfactant improves the applicability, the developability, and the like. Examples of the surfactant include nonionic surfactants such as polyoxyethylene lauryl ether and polyoxyethylene stearyl ether, commercially available products such as KP341 (manufactured by Shin-Etsu Chemical Co., Ltd.), Polyflow No. 75, Polyflow No. 95 (manufactured by Kyoeisha Chemical Co., Ltd.), EFTOP EF301, EFTOP EF303, EFTOP EF352 (manufactured by JEMCO, Inc.), Megafac F171, Megafac F173 (manufactured by DIC Corporation), Fluorad FC430, Fluorad FC431 (manufactured by Sumitomo 3M Ltd.), Asahi Guard AG710, Surflon S-382, Surflon SC-101, Surflon SC-102, Surflon SC-103, Surflon SC-104, Surflon SC-105, Surflon SC-106 (manufactured by Asahi Glass Co., Ltd.), and the like. These surfactants may be used either individually or in combination. The amount of the surfactant is normally 2 parts by mass or less based on 100 parts by mass of the resin (A). Note that a sensitizer, a halation inhibitor, an adhesion aids, a storage stabilizer, an anti-foaming agent, or the like may also be used.

### (Preparation of Composition Solution)

The radiation-sensitive resin composition according to one embodiment of the present invention is normally prepared as a composition solution by dissolving the components in a solvent so that the total solid content is 1 to 50 mass %, and preferably 3 to 25 mass %, and then filtering the solution through a filter having a pore size of about 0.02 μm, for example. Examples of the solvent used to prepare the composition solution include linear or branched ketones such as 2-butanone, 2-pentanone, and 3-methyl-2-butanone; cyclic ketones such as cyclopentanone, 3-methylcyclopentanone, and cyclohexanone; propylene glycol monoalkyl ether acetates such as propylene glycol monomethyl ether acetate, propylene glycol monoethyl ether acetate, and propylene glycol mono-n-propyl ether acetate; alkyl 2-hydroxypropionates such as methyl 2-hydroxypropionate, ethyl 2-hydroxypropionate, n-propyl 2-hydroxypropionate, and i-propyl 2-hydroxypropionate; alkyl 3-alkoxypropionates such as methyl 3-methoxypropionate and ethyl 3-methoxypropionate;

n-propyl alcohol, i-propyl alcohol, ethylene glycol monomethyl ether, ethylene glycol monoethyl ether, ethylene glycol mono-n-propyl ether, diethylene glycol dimethyl ether, diethylene glycol diethyl ether, diethylene glycol di-n-propyl ether, ethylene glycol monomethyl ether acetate, ethylene glycol monoethyl ether acetate, propylene glycol monomethyl ether, toluene, xylene, ethyl 2-hydroxy-2-methylpropionate, ethyl ethoxyacetate, ethyl hydroxyacetate, methyl 2-hydroxy-3-methylbutyrate, 3-methoxybutylacetate, 3-methyl-3-methoxybutylacetate, ethyl acetate, n-propyl acetate, methyl acetoacetoate, ethyl acetoacetate, methyl pyruvate, ethyl pyruvate, N-methylpyrrolidone, N,N-dimethylformamide, N,N-dimethylacetamide, diethylene glycol monoethyl ether, caproic acid, caprylic acid, benzyl acetate, ethyl benzoate, diethyl oxalate, diethyl maleate, γ-btltyrolactone, ethylene carbonate, propylene carbonate, and the like.

These solvents may be used either individually or in combination. Among these, linear or branched ketones, cyclic ketones, propylene glycol monoalkyl ether acetates, alkyl 2-hydroxypropionates, alkyl 3-alkoxypropionates, γ-butyrolactone, and the like are preferable.

### (Method of Forming Resist Pattern)

The radiation-sensitive resin composition according to one embodiment of the present invention may be particularly useful as a chemically-amplified resist. In the chemically-amplified resist, the acid-labile group included in the resin (A) dissociates due to an acid generated by the acid generating agent (B) upon exposure, so that the solublity of the exposed area of the resist in an alkaline developer increases. Therefore, the exposed area is dissolved (removed) in an alkaline developer to form a positive type resist pattern. When forming a resist pattern using the radiation-sensitive resin composition according to one embodiment of the present invention, a composition solution of the radiation-sensitive resin composition is applied to a substrate (e.g., silicon wafer or aluminum-coated wafer) by an appropriate coating method (e.g., rotational coating, cast coating, or roll coating) to form a resist film. The resist film is optionally prebaked (hereinafter may be referred to as “PB”), and exposed so as to form a given resist pattern.

Radiation used for exposure may be appropriately selected from visible rays, ultraviolet rays, far-ultraviolet rays, X-rays, charged particle rays, and the like depending on the type of the acid generating agent (B). It is preferable to use ArF excimer laser light (wavelength: 193 nm) or KrF excimer laser light (wavelength: 248 nm). The resist film is preferably subjected to post-exposure bake (PEB) after exposure. The dissociable reaction of the acid-labile group included in the resin (A) proceeds smoothly by employing the PEB. The PEB temperature is determined depending on the composition of the radiation-sensitive resin composition. However it is normally 30 to 200° C., and preferably 50 to 170° C.

In order to maximize the potential of the radiation-sensitive resin composition, an organic or inorganic anti-reflective film may be formed on the substrate, as disclosed in JP-A-H6-12452, for example. Moreover, a protective film may be formed on the resist film so that the resist film is not affected by basic impurities and the like contained in the environmental atmosphere, as disclosed in JP-A-H5-188598, for example. Further, these techniques may be used in combination.

The exposed resist film is developed to form a given resist pattern. An alkaline aqueous solution prepared by dissolving at least one alkaline compound (e.g., sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, ethyldimethylamine, triethanolamine, tetramethylammonium hydroxide, pyrrole, piperidine, choline, 1,8-diazabicyclo-[5.4.0]-7-undecene, and 1,5-diazabicyclo-[4.3.0]-5-nonene) in water is preferable as the developer used for development. The concentration of the alkaline aqueous solution is normally 10 mass % or less. If the concentration of the alkaline aqueous solution exceeds 10 mass %, the unexposed part may be dissolved in the developer.

An organic solvent may be added to the alkaline aqueous solution (developer), for example. Examples of the organic solvent include linear, branched, or cyclic ketones such as acetone, methyl ethyl ketone, methyl i-butyl ketone, cyclopentanone, cyclohexanone, 3-methylcyclopentanone, and 2,6-dimethylcyclohexanone; alcohols such as methanol, ethanol, n-propyl alcohol, i-propyl alcohol, n-butyl alcohol, t-butyl alcohol, cyclopentanol, cyclohexanol, 1,4-hexanediol, and 1,4-hexanedimethylol; ethers such as tetrahydrofuran and dioxane; esters such as ethyl acetate, n-butyl acetate, and i-amyl acetate; aromatic hydrocarbons such as toluene and xylene, phenol, acetonylacetone, dimethylformamide, and the like. These organic solvents may be used either individually or in combination. The amount of the organic solvent is preferably 100 vol % or less based on the amount of the alkaline aqueous solution. If the amount of the organic solvent exceeds 100 vol %, the exposed area may remain undeveloped due to a decrease in developability. An appropriate amount of a surfactant or the like may also be added to the alkaline aqueous solution (developer). Incidentally, after development using the alkaline aqueous solution (developer), the resist film is normally rinsed with water, and dried.

Note that radiation may be applied to the photoresist film via an immersion exposure liquid provided over the photoresist film (hereinafter may be referred to as “liquid immersion lithography”). Purified water, a long-chain or cyclic aliphatic compound, or the like may be used as the immersion liquid.

In order to prevent outflow of the acid generating agent and the like from the resist film during liquid immersion lithography, a liquid immersion lithography protective film may be formed on the resist film, as disclosed in JP-A-2005-352384, for example. When utilizing liquid immersion lithography, a resist pattern can be formed by the resist film obtained using the radiation-sensitive resin composition according to one embodiment of the present invention without providing a protective film (upper-layer film) on the resist film. In this case, the throughput is improved since it is unnecessary to form a protective film (upper-layer film).

### EXAMPLES

The invention is further described below by way of examples. Note that the invention is not limited to the following examples. In the examples and comparative examples, the unit “parts” refers to “parts by mass”, and the unit “%” refers to “mass %”, unless otherwise specified. The following property value measuring methods and property evaluation methods were employed.

### Weight Average Molecular Weight (Mw) and Number Average Molecular Weight (Mn)

The weight average molecular weight (Mw) and the number average molecular weight (Mn) were determined by gel permeation chromatography (GPC) using GPC columns manufactured by Tosoh Corporation (G2000HXL×2, G3000HXL×1, G4000HXL×1) at a flow rate of 1.0 ml/min and a column temperature of 40° C. (eluant: tetrahydrofuran, standard: monodisperse polystyrene). The dispersity (Mw/Mn) was calculated from the measurement results.

Sensitivity (mJ/cm²)

The developed wafer was observed using a high-resolution FEB system (“CG4000” manufactured by Hitachi High-Technologies Corporation). An exposure amount at which a line-and-space (1 L1S) pattern having a line width of 42 nm and the line width ratio of 1:1 was formed was determined to be an optimum exposure amount, and the optimum exposure amount was taken as the sensitivity. No problem occurs in practical applications when the sensitivity is 42.0 mJ/cm² or less.

### Dense Line Depth of Focus (μm)

A focus amplitude when the pattern dimensions resolved using a 42 nm 1L/1 S mask pattern were within ±10% of the mask design dimensions was taken as the dense line depth of focus. No problem occurs in practical applications when the dense line depth of focus is 0.15 μm or more.

### Isolated Line Depth of Focus (μm)

A focus amplitude when the dimensions of a 40 nm 1L/140 nm P pattern resolved using a 70 nm 1L/140 nm P mask pattern were within the range of 36 to 44 nm 1L/140 nm P was taken as the isolated line depth of focus. No problem occurs in practical applications when the isolated line depth of focus is 0.06 μm or more.

### MEEF

A exposure amount at which a 1:1 line-and-space (1L1S) pattern having a line width of 42 mm and the line width ratio of 1:1 was formed was determined to be an optimum exposure amount, and the five dimensions of a pattern resolved using a 40 nm, 41 nm, 42 nm, 43 nm, or 44 nm mask were measured. The mask size (horizontal axis) and the line width (vertical axis) were plotted on a graph, and the slope calculated by the least-square method was taken as the MEEF. A small MEEF indicates high resolution. No problem occurs in practical applications when the MEEF is 4.3 or less.

### LWR (nm)

The line width of a 42 nm 1L/1S pattern resolved at the optimum exposure amount was observed from above at an arbitrary ten points using a high-resolution FEB system (“CG4000” manufactured by Hitachi High-Technologies Corporation), and a variation (3σ) in line width was taken as the LWR. No problem occurs in practical applications when the LWR is 5.0 nm or less.

### Evaluation of Cross-Sectional Pattern Shape

The cross-sectional shape of the 42 nm line-and-space pattern used to measure the sensitivity was observed using a scanning type electron microscope (“S-4800” manufactured by Hitachi High-Technologies Corporation). A case where the line-and-space pattern had a T-top shape (i.e., a shape other than a rectangular shape) was evaluated as “Unacceptable”, and a case where the line-and-space pattern had a rectangular shape was evaluated as “Acceptable”.

### (Production of Resin (A))

A resin (A) was produced using the following compounds.

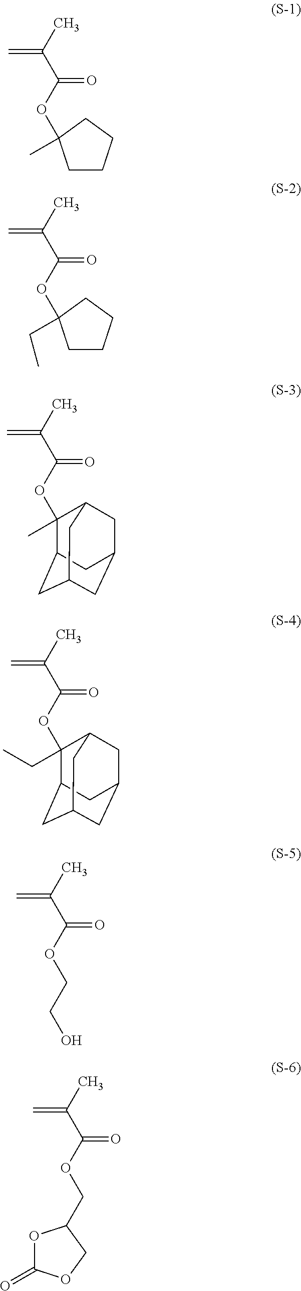

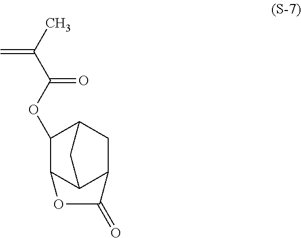

### Synthesis Example 1

21.54 g (50 mol %) of the compound (S-1) and 28.46 g (50 mol %) of the compound (S-7) were dissolved in 100 g of 2-butanone, and 2.10 g of dimethyl 2,2′-azobis(2-methylpropionate) was added to the solution to prepare a monomer solution. A three-necked flask (500 ml) charged with 50 g of 2-butanone was purged with nitrogen for 30 minutes, and heated to 80° C. with stirring. The monomer solution was added dropwise to the flask using a dropping funnel over 3 hours. The compounds were polymerized for 6 hours from the start of addition of the monomer solution.

After completion of polymerization, the polymer solution was cooled with water to 30° C. or less, and poured into 1000 g of methanol. A white powder that precipitated by this operation was collected by filtration. The white powder was dispersed in (washed with) 200 g of methanol in a slurry state, and filtered off. This operation was repeated once. The powder was then dried at 50° C. for 17 hours to obtain a white powdery copolymer (33.5 g, yield: 67%). The copolymer had an Mw of 6253 and a dispersity (Mw/Mn) of 1.65. As a result of ¹³C-NMR analysis, it was found that the ratio of repeating units derived from the compound (S-1) and repeating units derived from the compound (S-7) in the copolymer was 46:54 (mol %). The copolymer is referred to as “resin (A-1)”.

### Synthesis Examples 2 to 4

Resins (A-2) to (A-4) were produced in the same manner as in Synthesis Example 1, except for using the compounds shown in Table 1. The property values of the resins (A-2) to (A-4) are also shown in Table 1.

TABLE 1

| | | | Resin (A) | | | |
|---|---|---|---|---|---|---|
| | | | | | | Content ratio |
| | Compound | | | | | (mol %) of repeating |
| | | Amount | | | Mw/ | units derived |
| | Type | (mol %) | Type | Mw | Mn | from each compound |
| Synthesis | S-1 | 50 | A-1 | 6253 | 1.65 | 46 |
| Ex. 1 | S-7 | 50 | | | | 54 |
| Synthesis | S-2 | 40 | A-2 | 6200 | 1.43 | 40 |
| Ex. 2 | S-4 | 10 | | | | 9 |
| | S-7 | 50 | | | | 51 |
| Synthesis | S-2 | 15 | A-3 | 6812 | 1.70 | 16 |
| Ex. 3 | S-3 | 35 | | | | 32 |
| | S-6 | 20 | | | | 19 |
| | S-7 | 30 | | | | 33 |
| Synthesis | S-1 | 30 | A-4 | 5817 | 1.68 | 31 |
| Ex. 4 | S-4 | 10 | | | | 9 |
| | S-5 | 10 | | | | 9 |
| | S-7 | 50 | | | | 51 |

### (Production of Polymer (D))

A polymer (D) was produced using the following compounds.

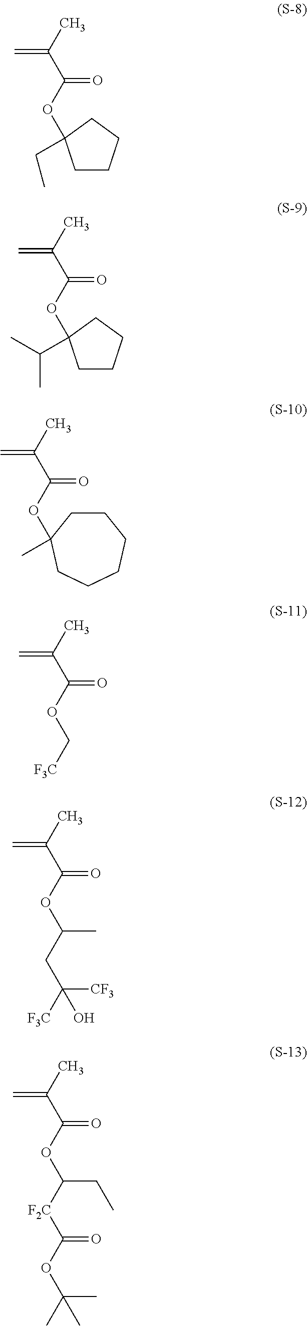

### Synthesis Example 5

35.81 g (70 mol %) of the compound (S-8) and 14.17 g (30 mol %) of the compound (5-11) were dissolved in 70 g of 2-butanone, and 3.23 g of dimethyl 2,2′-azobis(2-methylpropionate) was added to the solution to prepare a monomer solution. A three-necked flask (500 ml) charged with 30 g of 2-butanone was purged with nitrogen for 30 minutes, and heated to 80° C. with stirring. The monomer solution was added dropwise to the flask using a dropping funnel over 3 hours. The compounds were polymerized for 6 hours from the start of addition of the monomer solution.

After completion of polymerization, the polymer solution was cooled with water to 30° C. or less, and put in a 21 separating funnel. The polymer solution was diluted with 150 g of n-hexane, and mixed with 600 g of methanol. After the addition of 21 g of distilled water, the mixture was stirred, and allowed to stand for 30 minutes. The lower layer was then collected, and dissolved in propylene glycol monomethyl ether acetate. The solid content (polymer) of the propylene glycol monomethyl ether acetate solution was 60%. The resulting copolymer had an Mw of 7300 and a dispersity (Mw/Mn) of 1.6. As a result of ¹³C-NMR analysis, it was found that the copolymer had a fluorine content of 9.60 atom %, and the content ratio of repeating units derived from the compound (S-8) and repeating units derived from the compound (S-11) in the copolymer was 71:29 (mol %). The copolymer is referred to as “polymer (D-1)”.

### Synthesis Examples 6 and 7

Polymers (D-2) and (D-3) were produced in the same manner as in Synthesis Example 5, except for using the compounds shown in Table 2. The property values of the polymers (D-2) and (D-3) are also shown in Table 2.

TABLE 2

| | | | Polymer (D) | | | |
|---|---|---|---|---|---|---|
| | | | | | | Content ratio |
| | Compound | | | | | (mol %) of repeating |
| | | Amount | | | Mw/ | units derived |
| | Type | (mol %) | Type | Mw | Mn | from each compound |
| Synthesis | S-8 | 70 | D-1 | 7300 | 1.60 | 71 |
| Ex. 5 | S-11 | 30 | | | | 29 |
| Synthesis | S-10 | 60 | D-2 | 5900 | 1.41 | 60 |
| Ex. 6 | S-12 | 25 | | | | 24 |
| | S-13 | 15 | | | | 16 |
| Synthesis | S-9 | 65 | D-3 | 6030 | 1.44 | 66 |
| Ex. 7 | S-13 | 35 | | | | 34 |

### Example 1

100 parts of the resin (A-1) obtained in Synthesis Example 1, 12 parts of an acid generating agent (B-3), 0.4 parts of a compound (C1-1) (acid diffusion controller), 0.4 parts of a compound (C2-1) (acid diffusion controller), 3 parts of the fluorine-containing polymer (D-1) obtained in Synthesis Example 5, 2060 parts of a solvent (E-1), and 880 parts of a solvent (E-2) were mixed to prepare a composition solution of a radiation-sensitive resin composition.

### Examples 2 to 12 and Comparative Examples 1 to 8

A composition solution of a radiation-sensitive resin composition was prepared in the same mariner as in Example 1, except for changing the composition as shown in Table 3.

TABLE 3

| | Component (parts by mass) | | | | | |
|---|---|---|---|---|---|---|
| | | Acid generating | Acid diffusion | | | Radiation-sensitive |
| | Resin (A) | agent (B) | controller (C) | Polymer (D) | Solvent (E) | resin composition |
| Ex. 1 | A-1 (100) | B-3 (12) | C1-1 (0.4); C2-1 (0.4) | D-1 (3.0) | E-1 (2060); E-2 (880) | 1 |
| Ex. 2 | A-1 (100) | B-3 (12) | C1-1 (0.4); C2-4 (0.3) | D-1 (3.0) | E-1 (2060); E-2 (880) | 2 |
| Ex. 3 | A-1 (100) | B-3 (12) | C1-2 (0.3); C2-2 (0.6) | D-1 (3.0) | E-1 (2060); E-2 (880) | 3 |
| Ex. 4 | A-2 (100) | B-2 (12) | C1-1 (0.8); C2-1 (0.8) | D-2 (3.5) | E-1 (1870); E-2 (800); E-3 (30) | 4 |
| Ex. 5 | A-2 (100) | B-2 (12) | C1-2 (0.7); C2-4 (0.6) | D-3 (3.5) | E-1 (1870); E-2 (800); E-3 (30) | 5 |
| Ex. 6 | A-2 (100) | B-2 (12) | C1-3 (1.1); C2-3 (1.2) | D-2 (3.5) | E-1 (1870); E-2 (800); E-3 (30) | 6 |
| Ex. 7 | A-3 (100) | B-1 (10) | C1-1 (0.5); C2-1 (0.5) | — | E-1 (1870); E-2 (800); E-3 (30) | 7 |
| Ex. 8 | A-3 (100) | B-1 (10) | C1-2 (0.4); C2-1 (0.5) | — | E-1 (1870); E-2 (800); E-3 (30) | 8 |
| Ex. 9 | A-3 (100) | B-1 (10) | C1-3 (0.6); C2-1 (0.5) | — | E-1 (1870); E-2 (800); E-3 (30) | 9 |
| Ex. 10 | A-4 (100) | B-4 (18); B-5 (5) | C1-1 (1.2); C2-1 (1.3) | D-2 (3.0) | E-1 (2750); E-2 (1180); E-3 (100) | 10 |
| Ex. 11 | A-4 (100) | B-4 (18); B-5 (5) | C1-4 (1.6); C2-2 (1.6) | D-3 (3.0) | E-1 (2750); E-2 (1180); E-3 (100) | 11 |
| Ex. 12 | A-4 (100) | B-3 (18); B-5 (5) | C1-1 (1.2); C2-3 (1.9) | D-2 (3.0) | E-1 (2750); E-2 (1180); E-3 (100) | 12 |
| Comp. | A-1 (100) | B-3 (12) | C1-1 (0.8) | D-1 (3.5) | E-1 (2060); E-2 (880) | 13 |
| Ex. 1 | | | | | | |
| Comp. | A-1 (100) | B-3 (12) | C2-1 (0.8) | D-1 (3.5) | E-1 (2060); E-2 (880) | 14 |
| Ex. 2 | | | | | | |
| Comp. | A-2 (100) | B-2 (12) | C2-4 (1.6) | D-3 (3.5) | E-1 (1870); E-2 (800); E-3 (30) | 15 |
| Ex. 3 | | | | | | |
| Comp. | A-2 (100) | B-2 (12) | C3-1 (2.3) | D-2 (3.5) | E-1 (1870); E-2 (800); E-3 (30) | 16 |
| Ex. 4 | | | | | | |
| Comp. | A-3 (100) | B-1 (7.5) | C1-1 (0.7) | — | E-1 (1870); E-2 (800); E-3 (30) | 17 |
| Ex. 5 | | | | | | |
| Comp. | A-3 (100) | B-1 (10) | C1-1 (0.9) | — | E-1 (1870); E-2 (800); E-3 (30) | 18 |
| Ex. 6 | | | | | | |
| Comp. | A-4 (100) | B-4 (18) | C2-1 (1.9) | D-3 (3.0) | E-1 (2750); E-2 (1180); E-3 (100) | 19 |
| Ex. 7 | | | | | | |
| Comp. | A-4 (100) | B-4 (18); B-5 (5) | C2-1 (2.5) | D-2 (3.0) | E-1 (2750); E-2 (1180); E-3 (100) | 20 |
| Ex. 8 | | | | | | |

The following components were used in the examples and comparative examples.

### (Acid Generating Agent (B))

(B-1): triphenylsulfonium 2-bicyclo[2.2.1]hept-2-yl-1,1-difluoroethanesulfonate
(B-2): triphenylsulfonium 2-bicyclo[2.2.1]hept-2-yl-1,1,2,2-tetrafluoroethanesulfonate
(B-3): 4-cyclohexylphenyl•diphenylsulfonium nonafluoro-n-butanesulfonate
(B-4): triphenylsulfonium 1,1,2,2-tetrafluoro-6-(1-adamantanecarbonyloxy)hexane-1-sulfonate
(B-5): triphenylsulfonium 2-adamantyl-1,1-difluoroethanesulfonate

### (Acid Diffusion Controller (C))

(C1-1): N-t-butoxycarbonyl-4-hydroxypiperidine

### (C1-2): N-t-butoxycarbonylpyrrolidine

(C1-3): N-t-butoxycarbonyl-N′,N″-dicyclohexylamine
(C1-4): N-t-butoxycarbonyl-1-adamantylamine

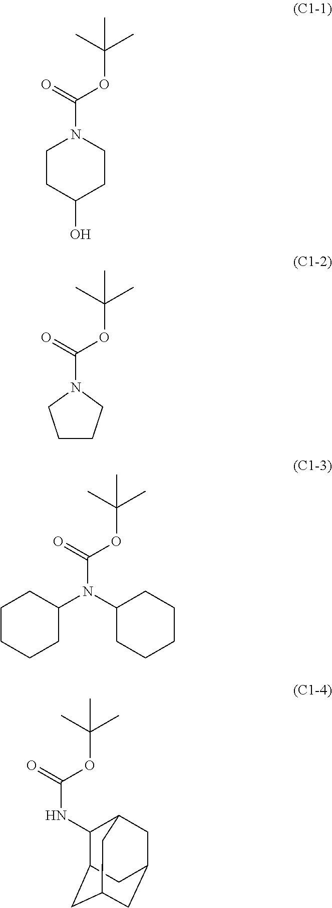

(C2-1): 2-phenylbenzimidazole
(C2-2): 1-(3-hydroxypropyl)-2-phenylbenzimidazole
(C2-3): 2,4,5-triphenylimidazole
(C2-4): 5-nitrobenzimidazole

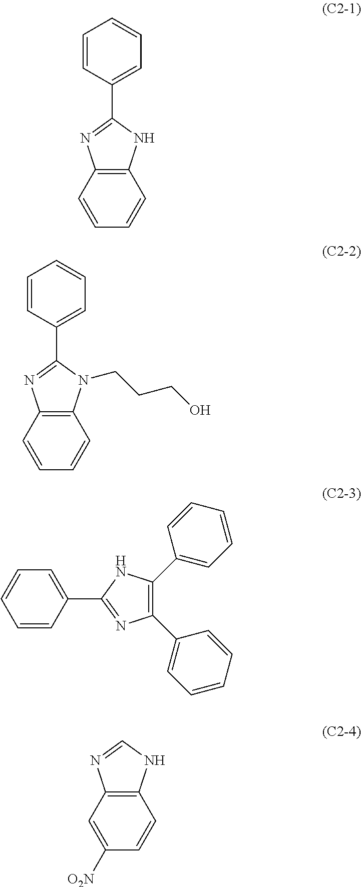

(C3-1): N-t-butoxycarbonyl-2-phenylbenzimidazole

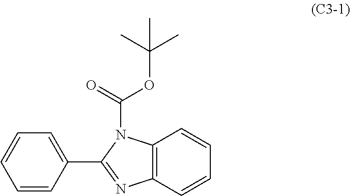

### (Solvent (E))

(E-1): propylene glycol monomethyl ether acetate
(E-2): cyclohexanone
(E-3): γ-butyrolactone

### (Evaluation of Example 1)

A silicon wafer on which an underlayer anti-reflective film (“ARC29” manufactured by Nissan Chemical Industries, Ltd.) (thickness: 105 nm) was formed, was used as a substrate. The composition solution of the radiation-sensitive resin composition prepared in Example 1 was spin-coated onto the substrate using a coater/developer (“Clean Track Lithius Pro i” manufactured by Tokyo Electron, Ltd.), and prebaked (PB) at 100° C. for 60 seconds using a hot plate to obtain a resist film having a thickness of 100 nm. The resist film was exposed via a mask pattern using an ArF immersion scanner (“S610C” manufactured by Nikon Corporation) (numerical aperture: 1.30). After performing PEB at 105° C. for 60 seconds, the resist film was developed at 23° C. for 30 seconds using a 2.38% tetramethylammonium hydroxide aqueous solution, rinsed with water, and dried to form a positive type resist pattern.

The sensitivity of the resist pattern was 28.0 mJ/cm², the dense line depth of focus was 0.18 μm, the isolated line depth of focus was 0.06 μm, the MEEF was 4.1, the LWR was 4.2 nm, and the cross-sectional shape was evaluated as “Acceptable”.

### (Evaluation of Examples 2 to 12 and Comparative Examples 1 to 8)

A resist pattern was formed in the same manner as in the evaluation of Example 1 (see Table 4). The evaluation results for each resist pattern are also shown in Table 4. In the evaluation of Examples 7 to 9 and Comparative Examples 5 and 6, a liquid immersion lithography upperlayer film (“NFC TCX041” manufactured by JSR Corporation) was spin-coated onto the resist film so as to have the thickness of 90 nm after forming the resist film.

TABLE 4

| | Radiation- | | | Thick- | Liquid immersion | | Dense line | Isolated line | | | Cross- |
|---|---|---|---|---|---|---|---|---|---|---|---|
| | sensitive resin | PB | PEB | ness | lithography | Sensitivity | depth of focus | depth of focus | | LWR | sectional |
| | composition | (° C.) | (° C.) | (nm) | upperlayer film | (mJ/cm²) | (μm) | (μm) | MEEF | (nm) | shape |
| Ex. 1 | 1 | 100 | 105 | 100 | Not provided | 28.0 | 0.18 | 0.06 | 4.1 | 4.2 | Acceptable |
| Ex. 2 | 2 | 100 | 105 | 100 | Not provided | 30.0 | 0.18 | 0.06 | 4.0 | 4.4 | Acceptable |
| Ex. 3 | 3 | 100 | 105 | 100 | Not provided | 27.0 | 0.15 | 0.06 | 4.2 | 4.6 | Acceptable |
| Ex. 4 | 4 | 100 | 85 | 100 | Not provided | 36.0 | 0.21 | 0.09 | 3.8 | 3.7 | Acceptable |
| Ex. 5 | 5 | 100 | 85 | 100 | Not provided | 37.0 | 0.21 | 0.12 | 3.9 | 3.9 | Acceptable |
| Ex. 6 | 6 | 100 | 85 | 100 | Not provided | 38.0 | 0.21 | 0.12 | 3.8 | 3.7 | Acceptable |
| Ex. 7 | 7 | 100 | 100 | 100 | Provided | 32.0 | 0.18 | 0.09 | 4.1 | 4.4 | Acceptable |
| Ex. 8 | 8 | 100 | 100 | 100 | Provided | 33.0 | 0.18 | 0.09 | 4.2 | 4.6 | Acceptable |
| Ex. 9 | 9 | 100 | 100 | 100 | Provided | 33.0 | 0.18 | 0.09 | 4.1 | 4.3 | Acceptable |
| Ex. 10 | 10 | 100 | 90 | 75 | Not provided | 41.0 | 0.21 | 0.12 | 3.6 | 3.9 | Acceptable |
| Ex. 11 | 11 | 100 | 90 | 75 | Not provided | 42.0 | 0.21 | 0.09 | 3.7 | 4.1 | Acceptable |
| Ex. 12 | 12 | 100 | 90 | 75 | Not provided | 42.0 | 0.18 | 0.09 | 3.8 | 4.2 | Acceptable |
| Comp. | 13 | 100 | 105 | 100 | Not provided | 28.0 | 0.15 | 0.03 | 4.7 | 5.3 | Acceptable |
| Ex. 1 | | | | | | | | | | | |
| Comp. | 14 | 100 | 105 | 100 | Not provided | 29.0 | 0.12 | 0.06 | 4.1 | 4.7 | Unacceptable |
| Ex. 2 | | | | | | | | | | | |
| Comp. | 15 | 100 | 85 | 100 | Not provided | 36.0 | 0.18 | 0.09 | 3.9 | 4.7 | Unacceptable |
| Ex. 3 | | | | | | | | | | | |
| Comp. | 16 | 100 | 85 | 100 | Not provided | 37.0 | 0.18 | 0.06 | 3.7 | 4.8 | Unacceptable |
| Ex. 4 | | | | | | | | | | | |
| Comp. | 17 | 100 | 105 | 100 | Provided | 33.0 | 0.15 | 0.06 | 4.5 | 5.3 | Acceptable |
| Ex. 5 | | | | | | | | | | | |
| Comp. | 18 | 100 | 100 | 100 | Provided | 32.0 | 0.18 | 0.06 | 4.6 | 5.3 | Acceptable |
| Ex. 6 | | | | | | | | | | | |
| Comp. | 19 | 100 | 90 | 75 | Not provided | 45.0 | 0.18 | 0.06 | 3.8 | 5.2 | Unacceptable |
| Ex. 7 | | | | | | | | | | | |
| Comp. | 20 | 100 | 90 | 75 | Not provided | 42.0 | 0.21 | 0.09 | 4.1 | 5.4 | Unacceptable |
| Ex. 8 | | | | | | | | | | | |

As shown in Table 4, a resist pattern that exhibits an excellent depth of focus, LWR, MEEF, and cross-sectional shape could be formed when using the radiation-sensitive resin compositions according to the examples of the present invention. As is clear from the evaluation results for Comparative Examples 1, 5, and 6, when using a radiation-sensitive resin composition including the acid diffusion controller (C) having only the compound (C1), the cross-sectional shape was evaluated as “Acceptable”, but the LWR increased. In addition, as is clear from the evaluation results for Comparative Examples 2, 3, 7, and 8, when using a radiation-sensitive resin composition including the acid diffusion controller (C) having only the compound (C2), the LWR was small, but the cross-sectional shape was evaluated as “Unacceptable”. Furthermore, as is clear from the evaluation results for Comparative Example 4, when using a radiation-sensitive resin composition including the acid diffusion controller (C) having only the compound (C3) which satisfies both nature of the compound (C1) and the compound (C2), the LWR was small, but the cross-sectional shape was evaluated as “Unacceptable”.

Since the radiation-sensitive resin composition according to the embodiments of the present invention exhibits an excellent depth of focus, LWR, MEEF, and cross-sectional shape, the radiation-sensitive resin composition may be very useful as a chemically-amplified resist used to produce semiconductor devices that are expected to be further miniaturized in the future.

Obviously, numerous modifications and variations of the present invention are possible in light of the above teachings. It is therefore to be understood that within the scope of the appended claims, the invention may be practiced otherwise than as specifically described herein.

1. A radiation-sensitive resin composition comprising:
an acid-labile group-containing resin;
a radiation-sensitive acid generating agent; and
an acid diffusion controller including a first compound shown by a general formula (1-1) and a second compound shown by a general formula (1-2) or a general formula (1-3), 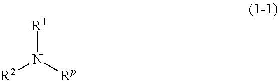
wherein each of R¹ and R² individually represents a hydrogen atom, a linear or branched alkyl group, a cycloalkyl group, an aryl group or an aralkyl group, or
each of R¹ and R² individually represents a hydrogen atom, a linear or branched alkyl group, a cycloalkyl group, an aryl group or an aralkyl group and R¹ and R² bond to each other to form a substituted or unsubstituted heterocyclic hydrocarbon group having 1 to 20 atoms together with a nitrogen atom bonded to R¹ and R², and
R^{p} represents an acid-labile group, 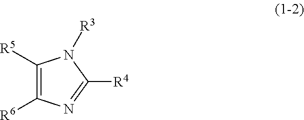
wherein R³ represents a hydrogen atom, a substituted or unsubstituted alkyl group having 1 to 20 carbon atoms, a substituted or unsubstituted alicyclic hydrocarbon group having 3 to 20 carbon atoms, an alkenyl group having 2 to 20 carbon atoms, a substituted or unsubstituted aryl group, or a substituted or unsubstituted heteroaryl group, and
each of R⁴ to R⁶ individually represents a hydrogen atom or a substituted or unsubstituted aryl group, or
each of R⁴ to R⁶ individually represents a hydrogen atom or a substituted or unsubstituted aryl group and two of R⁴ to R⁶ bond to each other to form a ring that optionally includes a heteroatom, 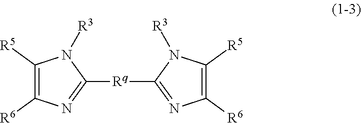
wherein R³ represents a hydrogen atom, a substituted or unsubstituted alkyl group having 1 to 20 carbon atoms, a substituted or unsubstituted alicyclic hydrocarbon group having 3 to 20 carbon atoms, an alkenyl group having 2 to 20 carbon atoms, a substituted or unsubstituted aryl group, or a substituted or unsubstituted heteroaryl group,
R^{q} represents a single bond, a substituted or unsubstituted methylene group, a substituted or unsubstituted alkylene group having 2 to 20 carbon atoms, a substituted or unsubstituted alicyclic hydrocarbon group having 3 to 20 carbon atoms, an alkenylene group having 2 to 20 carbon atoms, a substituted or unsubstituted arylene group, or a substituted or unsubstituted heteroarylene group, and
each of R⁵ and R⁶ individually represents a hydrogen atom or a substituted or unsubstituted aryl group, or
each of R⁵ and R⁶ individually represents a hydrogen atom or a substituted or unsubstituted aryl group and R⁵ and R⁶ bond to each other to form a ring that optionally includes a heteroatom.

2. The radiation-sensitive resin composition according to claim 1, wherein an amount of the second compound is 1 to 99 parts by mass based on 100 parts by mass of the acid diffusion controller.

3. The radiation-sensitive composition according to claim 1, wherein the first compound is a compound shown by a general formula (1-1a), 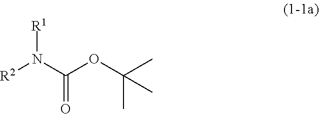
wherein each of R¹ and R² individually represents a hydrogen atom, a linear or branched alkyl group, a cycloalkyl group, an aryl group, or an aralkyl group, or
each of R¹ and R² individually represents a hydrogen atom, a linear or branched alkyl group, a cycloalkyl group, an aryl group, or an aralkyl group and R¹ and R² bond to each other to form a substituted or unsubstituted heterocyclic hydrocarbon group having 1 to 20 atoms together with a nitrogen atom bonded to R¹ and R².

4. The radiation-sensitive resin composition according to claim 1, wherein the acid-labile group-containing resin includes a first repeating unit shown by a general formula (2-1) and a second repeating unit shown by a general formula (2-2), 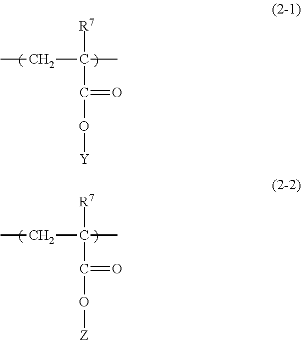
wherein R⁷ represents a hydrogen atom, a methyl group, or a trifluoromethyl group, Y represents an acid-labile group, and Z represents a group including a lactone skeleton or a cyclic carbonate structure.

5. The radiation-sensitive resin composition according to claim 4, wherein Yin the general formula (2-1) represents a group shown by a general formula (1), 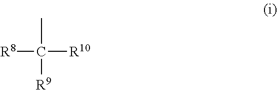
wherein R⁸ represents an alkyl group having 1 to 4 carbon atoms or a monovalent alicyclic hydrocarbon group having 4 to 20 carbon atoms, and
each of R⁹ and R¹⁰ individually represents an alkyl group having 1 to 4 carbon atoms or a monovalent alicyclic hydrocarbon group having 4 to 20 carbon atoms, or
each of R⁹ and R¹⁰ individually represents an alkyl group having 1 to 4 carbon atoms or a monovalent alicyclic hydrocarbon group having 4 to 20 carbon atoms and R⁹ and R¹⁰ bond to each other to form an alicyclic hydrocarbon group having 4 to 20 carbon atoms together with a carbon atom bonded to R⁹ and R¹⁰.

6. The radiation-sensitive resin composition according to claim 1, further comprising a fluorine-containing polymer.

7. The radiation-sensitive resin composition according to claim 6, wherein an amount of the fluorine-containing polymer is 0.1 to 20 parts by mass based on 100 parts by mass of the acid-labile group-containing resin.

8. The radiation-sensitive resin composition according to claim 3, wherein the acid-labile group-containing resin includes a first repeating unit shown by a general formula (2-1) and a second repeating unit shown by a general formula (2-2), 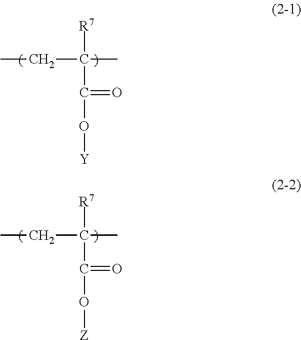
wherein, R⁷ represents a hydrogen atom, a methyl group, or a trifluoromethyl group, Y represents an acid-labile group, and Z represents a group including a lactone skeleton or a cyclic carbonate structure.

9. The radiation-sensitive resin composition according to claim 8, wherein Y in the general formula (2-1) represents a group shown by a general formula (1), 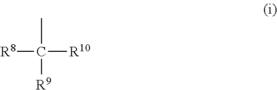
wherein R⁸ represents an alkyl group having 1 to 4 carbon atoms or a monovalent alicyclic hydrocarbon group having 4 to 20 carbon atoms, and
each of R⁹ and R¹⁰ individually represents an alkyl group having 1 to 4 carbon atoms or a monovalent alicyclic hydrocarbon group having 4 to 20 carbon atoms, or
each of R⁹ and R¹⁰ individually represents an alkyl group having 1 to 4 carbon atoms or a monovalent alicyclic hydrocarbon group having 4 to 20 carbon atoms and R⁹ and R¹⁰ bond to each other to form an alicyclic hydrocarbon group having 4 to 20 carbon atoms together with a carbon atom bonded to R⁹ and R¹⁰.

10. The radiation-sensitive resin composition according to claim 3, further comprising a fluorine-containing polymer.

11. The radiation-sensitive resin composition according to claim 4, further comprising a fluorine-containing polymer.

12. The radiation-sensitive resin composition according to claim 5, further comprising a fluorine-containing polymer.

13. The radiation-sensitive resin composition according to claim 8, further comprising a fluorine-containing polymer.

14. The radiation-sensitive resin composition according to claim 9, further comprising a fluorine-containing polymer.
